(19) United States
(12) Patent Application Publication
(10) Pub. No.: US 2007/0075628 A1
(43) Pub. Date: Apr. 5, 2007

(54) ORGANIC LIGHT EMITTING DEVICES HAVING LATENT ACTIVATED LAYERS

(75) Inventors: Larry Neil Lewis, Scotia, NY (US); Qinglan Huang, Niskayuna, NY (US); Donald Franklin Foust, Glenville, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/536,228

(22) Filed: Sep. 28, 2006

Related U.S. Application Data
(63) Continuation-in-part of application No. 11/243,194, filed on Oct. 4, 2005.

(51) Int. Cl. H01L 51/52; H01L 51/56

(52) U.S. Cl. 313/503; 428/690; 428/917; 428/457; 427/66; 427/123

(57) ABSTRACT

An organic light emitting device with a latent activator material is presented. An organic light emitting device including activation products of a latent activator material is also presented. Embodiments of patterned organic light emitting devices are also contemplated wherein patterning can occur prior or post fabrication of the devices. A method of fabricating an organic light emitting device with a latent activator material or with activation products of an activator material is also provided.

### CROSS REFERENCE TO RELATED APPLICATIONS

This application is a continuation in part of copending application, Ser. No. 11/243194, filed Oct. 4, 2005, the entire contents of which is incorporated by reference herein.

### STATEMENT REGARDING FEDERALLY SPONSORED RESEARCH & DEVELOPMENT

This invention was made with Government support under contract number 70NANB3H3030 awarded by National Institute of Standards and Technology. The Government has certain rights in the invention.

### BACKGROUND

The invention relates generally to organic electronic devices. The invention in particular relates to organic light emitting devices.

Organic electronic devices include organic light emitting devices and organic photovoltaic devices. Organic electronic devices operate by injection of charges, which combine to result in radiation of energy as in a light emitting device, or separation of charges as in a photovoltaic device. As will be appreciated by one skilled in the art, an organic light emitting device (OLED) typically includes at least one organic layer sandwiched between two electrodes. The OLED may include additional layers such as a hole injection layer, a hole transport layer, an emissive layer, and an electron transport layer. Upon application of an appropriate voltage to the OLED, the injected positive and negative charges recombine in the emissive layer to produce light.

The addition of certain materials in the device can facilitate charge injection, transport, recombination, separation, etc. In some examples, such addition of materials may lead to increase in conductivity in a system or device by increasing the number of charge carriers (electrons or holes) present in the system. Traditional approaches include such processes as addition of acidic compounds (addition of hole donors or electron acceptors) and reducing materials like metal fluorides, alkali or alkali earth metals (addition of electron donors). The reactive nature of these materials can cause problem when forming multi-layer devices. For example, strong acids present in a layer typically migrate upon addition of layers to the top of the layer. Furthermore, known electron donors typically react with air or moisture and may decompose during manufacture.

Traditional methods for generating a low work function cathode involve vapor deposition. Vapor deposition is not desirable for continuous manufacture.

Organic light emitting devices include light panels. Organic light emitting devices operate by injection of charges, which combine to result in radiation of energy as in a light emitting device, or separation of charges as in a photovoltaic device. As will be appreciated by one skilled in the art, an organic light emitting device (OLED) typically includes at least one organic layer sandwiched between two electrodes. The OLED may include additional layers such as a hole injection layer, a hole transport layer, an emissive layer, and an electron transport layer. Upon application of an appropriate voltage to the OLED, the injected positive and negative charges recombine in the emissive organic layer to produce light.

The cathode of an OLED has best performance with a low work-function. Traditional methods for generating a low work-function cathode for an OLED involve vapor deposition. Vapor deposition is not desirable for continuous manufacture using air sensitive precursors. The manufacture of OLEDs normally require inerting of the work environment during manufacture.

Accordingly, a technique is needed to address one or more of the foregoing problems in organic optoelectronic devices, such as light emitting devices.

U.S. Pat. No. 4,249,105 Kaegawa et al, (1981) discloses that a cathode for gas discharge display panel can be made by the thermal decomposition of barium bis azide to produce Ba and Ba₃N₂. See Col. 5, lls. 11-20.

U.S. Pat. No. 5,534,312 Hill et al. (1996) discloses spin coating a film of a metal complex onto a substrate in air, and subjecting the complex to light. See the Abstract.

U.S. Patent Application 2001/0005112 Saito et al discloses that an electron emission substance having a work function of not more than 2 to 3 [eV] is used to make a field emission cathode from a metal precursor. See paragraphs [0153] and [0154].

U.S. Patent Application 2004/0101988 Al Roman et al discloses creating masks from ligands that spontaneously thermally decompose. See paragraphs [01141-[0117].

U.S. Patent Application 2004/0164293 Maloney et al discloses a method of creating a barrier layer by depositing a precursor at atmospheric conditions and converting the precursor to an imaging layer. See paragraphs [0008], [0013], [0018] and [0158].

### BRIEF DESCRIPTION

Briefly, in accordance with aspects of the present technique, an organic light emitting device is presented. The organic light emitting device includes a substrate and at least one layer including a latent activator material.

In accordance with further aspects of the present technique, an organic light emitting device is presented. The organic light emitting device includes a substrate and at least one layer including activation products of a latent activator material.

According to further aspects of the present technique, a method of fabricating an organic light emitting device with a latent activator material or with activation products of a latent activator material is presented. The invention in particular relates to organic light emitting devices.

An OLED device has a cathode layer comprising a reaction product of at least one metal precursor capable of releasing at least one low work function metal when exposed to heat or light. In one embodiment the at least one low work function metal has a work function value of less than 3.0 eV.

In another embodiment, the at least one low work function metal is selected from the group consisting essentially of the alkali metal series of elements in Group 1 of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); and the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium.

In another embodiment the low work function metal comprises barium.

In another embodiment the metal precursor comprises an organometallic compound having a formula RₓM, wherein M is a metal, ₓ has a value of from 1 to 3, the value being the valence of the metal and R is an aliphatic or aromatic radical.

In another embodiment the metal precursor comprises an organometallic compound having a formula RₓM, wherein M is a Group II metal, or a lanthanide series metal or any combinations thereof, ₓ has a value of 2 when M is a group II metal and a value of from 2 to 3 when M is a lanthanide series metal, and R is an aliphatic or aromatic radical.

In another embodiment, the metal precursor comprises a material comprising a cyclopentadienyl derivative of an alkaline-earth metal, bis(tetra-i-propyl-cyclopentadienyl) barium, bis(tetra-i-propyl-cyclopentadienyl) calcium, bis(penta-isopropylcyclopentadienyl)M, where M is calcium, barium or strontium, bis(tri-t-butylcyclopentadienyl)M; wherein M is calcium, barium or strontium, a cyclopentadienyl derivative of a lanthanide transition metal, a fluorenyl derivative of an alkaline-earth metal, bis(fluorenyl)calcium, bis(fluorenyl)barium, or a fluorenyl derivative of a lanthanide transistion metal or any combinations thereof.

In another embodiment, the metal precursor comprises a compound of formula M(N₃)ₓ, wherein M is alkali metal series of elements in Group 1 (IUPAC style) of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is a rare earth metal.

In another embodiment, the metal precursor comprises barium bis azide of the formula Ba(N₃)₂.

In another embodiment, the organic light emitting device comprises:

a) a substrate,

b) at least one cathode layer covering at least part of one surface of the substrate, the cathode layer comprising a reaction product from decomposing at least one metal precursor of formula M(N₃)ₓ, wherein M is selected from the group consisting essentially of the alkali metal series of elements in Group 1 (IUPAC style) of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is a rare earth metal;

c) an anode layer material covering at least a portion of a second substrate: and

d) an organic light emitting material positioned between the cathode layer and the anode layer whereby light is emitted when opposing charges are applied to the anode and cathode layers.

In another embodiment the cathode layer material comprises barium.

In another embodiment the metal precursor comprises an organometallic compound having a formula R₂M, wherein M is an alkaline earth metal, and R is an aliphatic or aromatic radical or a substituted aliphatic or aromatic radical.

In another embodiment the metal precursor comprises an organometallic compound having a formula RₓM, wherein M is a Group II metal, or a lanthanide series metal or any combinations thereof, wherein R is an aliphatic or aromatic radical and wherein ₓ has a value of 2 when M is a group II metal and a value of from 2 to 3 when M is a lanthanide series metal.

In another embodiment the metal precursor comprises a material comprising a cyclopentadienyl derivative of an alkaline-earth metal, bis(tetra-i-propyl-cyclopentadienyl)barium, bis(tetra-i-propyl-cyclopentadienyl) calcium, bis(penta-isopropylcyclopentadienyl)M, where M is calcium, barium or strontium, and bis(tri-t-butylcyclopentadienyl)M wherein M is calcium, barium or strontium: a cyclopentadienyl derivative of a lanthanide transition metal, a fluorenyl derivative of an alkaline-earth metal, bis(fluorenyl)calcium, bis(fluorenyl)barium, or a fluorenyl derivative of a lanthanide transistion metal or any combinations thereof.

In another embodiment the metal precursor comprises a compound of formula M(N₃)ₓ, wherein M is selected from the group consisting essentially of the alkali metal series of elements in Group 1 (IUPAC style) of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is a rare earth metal.

In another embodiment the metal precursor comprises barium bis azide.

In another embodiment the method of making an organic light emitting device comprises:

a) applying to a substrate in atmospheric air a solution of at least one metal precursor comprising an azide of at least one metal, M(N₃)ₓ, wherein M is selected from the group consisting essentially of the alkali metal series of elements in Group 1 (IUPAC style) of the periodic table: including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is a rare earth metal.

b) exposing the at least one metal precursor to heat or light to release the at least one metal .

In one embodiment of the method, the at least one metal precursor is barium bis azide.

Another embodiment of the method of making an organic light emitting diode comprises the steps of:

a) providing at least one metal precursor capable of transforming into a deposited, metal-containing layer;

b) forming a layer comprising the at least one metal precursor atop the substrate;

c) converting the precursor layer so as to form a deposited, metal-containing cathode;

d) combining a light emitting organic layer with the cathode and;

e) combining an anode with the cathode and light emitting layer, the light emitting layer being positioned between the cathode and the anode.

In an embodiment of the above method, the at least one metal precursor comprises a compound of formula M(N₃)ₓ, wherein M is M is selected from the group consisting essentially of the alkali metal series of elements in Group 1 (IUPAC style) of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is selected from the lanthanides.

In the above method the at least one metal precursor is a metal azide. The at least one metal precursor can be barium bis azide.

In the above method the converting is accomplished using an energy source selected from the group consisting of light, heat, electron beam irradiation, ion beam irradiation, and mixtures thereof.

In the above method the at least one metal precursor is applied as a fluid.

In the above method the cathode has a work function value of less than 3.0 eV.

In another embodiment, the light emitting devices described above comprise a light panel. In the light panel the cathode layer material comprises barium in one embodiment. In another embodiment of the light panel, the at least one metal precursor comprises barium bis azide.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a cross-sectional representation of an exemplary embodiment of an organic light emitting device, according to aspects of the present technique;

FIG. 2 is a cross-sectional representation of another exemplary embodiment of an organic light emitting device, according to aspects of the present technique;

FIG. 3 is a cross-sectional representation of another exemplary embodiment of an organic light emitting device, according to aspects of the present technique;

FIG. 4 is a cross-sectional representation of another exemplary embodiment of an organic light emitting device, according to aspects of the present technique;

FIG. 5 is a cross-sectional representation of another exemplary embodiment of an organic light emitting device, according to aspects of the present technique;

FIG. 6 is a cross-sectional representation of another exemplary embodiment of an organic light emitting device, according to aspects of the present technique;

FIGS. 7-22 are cross-sectional representations of exemplary processes of fabricating organic light emitting devices illustrated in FIGS. 1-6, according to aspects of the present technique;

FIG. 23 is a flow chart illustrating an exemplary process of fabricating the organic light emitting device according to aspects of the present technique;

FIG. 24 is a flow chart illustrating an exemplary process of fabricating the organic light emitting device according to aspects of the present technique;

FIG. 25 is a flow chart illustrating an exemplary process of fabricating the organic light emitting device according to aspects of the present technique;

FIG. 26 is a graph illustrating the efficiency versus current density profiles of organic light emitting devices according to aspects of the present technique.

FIGS. 26 and 27 show current efficiency and power efficiency as calculated for Example 6.

FIGS. 28 and 29 show current efficiency and power efficiency as calculated for Example 7.

FIG. 30 shows the current efficiency v. Voltage.

FIG. 31 shows the power efficiency v. voltage for the first OLED of Example 8.

FIG. 32 is another graph showing the current efficiency v. voltage and FIG. 33 is another graph showing the power efficiency v. voltage for the OLED of Example 8 made using polyethylene glycol.

In the following specification and the claims which follow, reference will be made to a number of terms which shall be defined to have the following meanings. The singular forms “a”, “an” and “the” include plural referents unless the context clearly dictates otherwise. The term “electroactive” as used herein refers to a material that is (1) capable of transporting, blocking or storing charge (either positive charge or negative charge), (2) light-absorbing or light emitting, typically although not necessarily fluorescent, and/or (3) useful in photo-induced charge generation, and/or 4) of changing color, reflectivity, transmittance upon application of bias. An “electroactive device” is a device comprising an electroactive material. In the present context an electroactive layer is a layer for an electroactive device, which comprises at least one electroactive organic material or at least one electrode material. As used herein the term “organic material” may refer to either small molecular organic compounds, or high molecular organic compounds, including but not limited to dendrimers, or large molecular polymers, including oligomers with a number of repeat unit ranging from 2 to 10, and polymers with a number of repeat unit greater than 10.

]As used herein, the term “activator material” refers to materials that enable increase in charge injection, in charge transport, in charge recombination, or in charge separation. In some embodiments, the activator materials are hole or electron donors. Examples of activator materials include but are not limited to photoacids (or interchangeably photogenerated acids) and photobases (or interchangeably photogenerated bases).

As used herein, the term “activated layer” refers to a layer with at least one activator material. In a non-limiting example, an activated layer includes a photoacid or a photobase. In a further example, a layer with hole donors, a p-activated layer, may be expected to experience an increase in work function as compared a layer without the activator material, whereas a layer with electron donors, a n-activated layer, is expected to experience a decrease in work function compared to a layer without the activator material.

As used herein, the term “latent activator material” refers to materials whose activation products comprise at least one activator material. Examples of latent activator materials include but are not limited to photoacid generators and photobase generators.

As used herein, the term “latent activated layer” refers to a layer with at least one latent activator material. In a non-limiting example, a latent activated layer is a charge transport layer comprising poly(3,4-ethylenedioxythiophene) tetramethacrylate (PEDOT) material further including a latent activator material such as diphenyliodonium hexafluorphosphate.

As used herein, the term “activation” refers to using light or heat to generate an activator material.

As used herein, the term “activation products” refers to direct or indirect reactions products due to thermal or photo activation of a latent activator material. For example, a photoacid is the activation product of a photoactivated photoacid generator latent activator material.

As used herein, the term “passivation” refers to inactivating an activated region in a layer, by irradiating a latent activator material in contact with the activated region, to provide counter activator material to neutralize the activator material in the activated region. For example, a base material can be neutralized by bringing into contact with the base material a latent activator material such as a photoacid generator, and activating the photoacid generator to release the photoacid to neutralize the base material.

As used herein, the term “disposed over” or “deposited over” refers to disposed or deposited immediately on top of and in contact with, or disposed or deposited on top of but with intervening layers therebetween.

The term “alkyl” as used in the various embodiments of the present invention is intended to designate linear alkyl, branched alkyl, aralkyl, cycloalkyl, bicycloalkyl, tricycloalkyl and polycycloalkyl radicals comprising carbon and hydrogen atoms, and optionally containing atoms in addition to carbon and hydrogen, for example atoms selected from Groups 15, 16 and 17 of the Periodic Table, such as halogen atoms. Alkyl groups may be saturated or unsaturated, and may comprise, for example, vinyl or allyl. The term “alkyl” also encompasses that alkyl portion of alkoxide groups. Unless otherwise noted, in various embodiments normal and branched alkyl radicals are those containing from 1 to about 32 carbon atoms, and comprise as illustrative non-limiting examples C₁-C₃₂ alkyl (optionally substituted with one or more groups selected from C₁-C₃₂ alkyl, C₃-C₁₅ cycloalkyl or aryl); and C₃-C₁₅ cycloalkyl optionally substituted with one or more groups selected from C₁-C₃₂ alkyl or aryl. Some illustrative, non-limiting examples comprise methyl, ethyl, n-propyl, isopropyl, n-butyl, sec-butyl, tertiary-butyl, pentyl, neopentyl, hexyl, heptyl, octyl, nonyl, decyl, undecyl and dodecyl. Some particular illustrative non-limiting examples of cycloalkyl and bicycloalkyl radicals comprise cyclobutyl, cyclopentyl, cyclohexyl, methylcyclohexyl, cycloheptyl, bicycloheptyl and adamantyl. In various embodiments aralkyl radicals comprise those containing from 7 to about 14 carbon atoms; these include, but are not limited to, benzyl, phenylbutyl, phenylpropyl, and phenylethyl. The term “aryl” as used in the various embodiments of the present invention is intended to designate substituted or unsubstituted aryl radicals comprising from 6 to 20 ring carbon atoms. Some illustrative non-limiting examples of aryl radicals include C₆-C₂₀ aryl optionally substituted with one or more groups selected from C₁-C₃₂ alkyl, C₃-C₁₅ cycloalkyl, aryl, and functional groups comprising atoms selected from Groups 15, 16 and 17 of the Periodic Table. Some particular illustrative, non-limiting examples of aryl radicals comprise substituted or unsubstituted phenyl, biphenyl, tolyl, xylyl, naphthyl and binaphthyl.

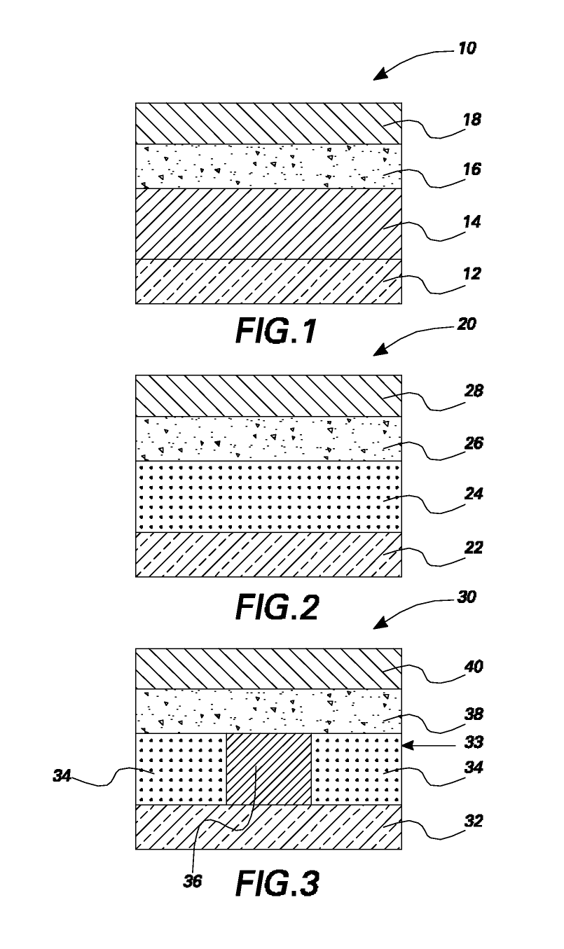

In accordance with one embodiment of the present invention there is provided an organic light emitting device comprising at least one latent activated layer including at least one latent activator material. Referring to FIG. 1, a first exemplary embodiment of an organic light emitting device (OLED) 10 is illustrated. In the illustrated embodiment, the light emitting device 10 is shown to include a first electrode 12, a latent activated layer 14 with a latent activator material, an electroactive layer 16 and a second electrode 18. In a non-limiting example, the first electrode is an anode, the latent activated layer is a hole injection and/or transport layer, the electroactive layer is a light emitting layer and the second electrode is a cathode. As will be appreciated by one skilled in the art, in alternate embodiments of the present technique, a lesser or greater number of electroactive layers may be present.

The latent activated layer may further include a material such a hole transport material, a hole injection material, an electron transport material, an electron injection material, a photoabsorption material, an electroluminescent material, a cathode material or an anode material or any combinations thereof.

The latent activator material may be an inorganic material, or organometallic material, or an organic material, or polymeric material, or any combinations thereof. In some embodiments the activator material is present as a dispersant in an organic matrix. In certain embodiments, the latent activator material is a material with at least one photoacid generating functional group, or photobase generating functional group or thermoacid generating functional group or any combinations thereof. Latent hole donor materials include but are not limited to photoacid or a thermoacid generators and latent electron donor materials include but are not limited to photobase generators and organometallic compounds generating a zero oxidation state metal on activation.

For example, a photoacid generator, diphenyliodonium hexafluorophosphate (Ph₂IPF₆) may be used as a latent activator material for p-activation.
Ph₂IPF₆ (1)
Typically on photoactivation, phenyl and phenyliodine radicals are generated. 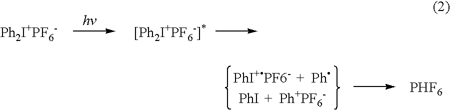
The photo generated phenyl (Ph^{+*}) and phenyliodine (PhI^{+*}) radicals are highly reactive species and are expected to further react with solvents or other impurities to generate hexafluorophosphoric acid, which acts as a p-activator. Photoacid generation is well known in the art. It is described in many references, such as “Crivello, Journal of Polymer Science part A: Polymer Chemistry, Volume 37 pp 4241-4254“, which is incorporated in its entirety herein by reference.

In an example of latent n-activation, an organometallic compound such as bis(fluorenyl)calcium may be used as a latent activator material. 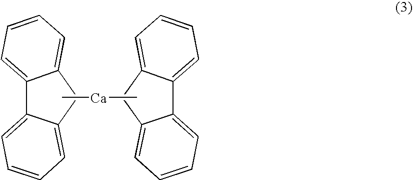
On activation, bis(fluorenyl)calcium is expected to undergo reductive elimination reaction to form metal in zero oxidation state and organic products. The metal acts as an electron donor.

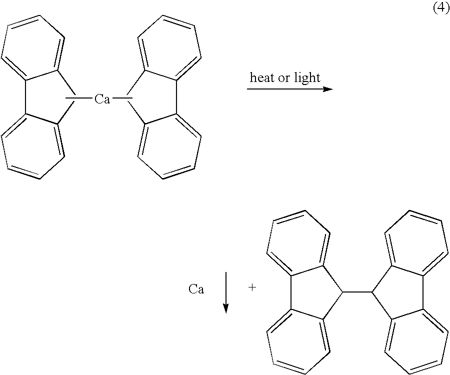

In some embodiments, the latent activated layer comprises 100% by weight of the latent activator materials. In certain other embodiments, the latent activator material is present in a range from about 99% to 0.1% by weight of the latent activated layer. In other embodiments, the latent activator material is present in a range from about 90% to about 20% of the latent activated layer. In still further embodiments, the latent activator material is present in a range from about 90% to about 50% of the latent activated layer. In some other embodiments the latent activator material may be present in a quantity as low as 100 parts per million of the total latent activated layer composition.

Non-limiting examples of photoacid generators include onium salts, iodonium salts, sulphonium salts, oxonium salts, halonium salts, phosphonium salts, nitrobenzyl esters, sulfones, phosphates, N-hydroxyimidosulfonates, a diphenyliodonium hexafluorophosphate, a diazonaphthoquinone, a diphenyliodonium triflate, a diphenyliodonium p-toluenesulfonate, triarylsulfonium sulfonates, a (p-methylphenyl, p-isopropylphenyl)iodonium tetrakis(pentafluorophenyl)borate, a bis(isopropylphenyl)iodonium hexafluoroantimonate, a bis(n-dodecylphenyl)iodonium hexafluoroantimonate and like materials.

Examples of thermoacid generators include but not are not limited to thiolanium salts, benzylthiolanium hexafluoro-propane-sulfonate, nitrobenzyl ester, 2-nitrobenzyl tosylate, amine triflates, iodonium salts, combination of iodonium salts with free radical generator such as benzopinacol, iodonium salts in combination with metal salts and like materials.

Non-limiting examples of photobase generators include O-acyloxime, quartenary ammonium salts, O-phenylacetyl-2-acetonaphthone oxime, benzoyloxycarbonyl derivatives, O-nitrobenzyl N-cyclohexylcarbamate, nifedipine, a N-methylnifedipine and like materials.

In another embodiment of the present invention, the latent activator material comprises an organometallic, which on thermal or optical activation releases the metal in its zero oxidation state. Non-limiting examples of such metals include Group I metals and Group II metals, Group III metals, Group IV metals, scandium, yttrium, and the lanthanide series of metals. In one embodiment the activator material is of formula R₂M, wherein M is a metal and R is an aliphatic or aromatic radical. In some embodiments, M is a Group II metal such as but not limited to calcium, strontium, barium, and magnesium, or a lanthanide series of metal such as but not limited to lanthanum, cerium, europium, praseodymium and neodymium. Non-limiting examples of such organometallic compounds include cyclopentadienyl derivatives of alkaline-earth metals or lanthanide group transition metals such as bis(tetra-i-propyl-cyclopentadienyl)barium, bis(tetra-i-propyl-cyclopentadienyl)calcium, bis(penta-isopropylcyclopentadienyl)M, where M is calcium, barium or strontium and bis(tri-t-butylcyclopentadienyl)M, where M is calcium, barium or strontium and fluorenyl derivatives of alkaline earth metals or lanthanide group transition metals, such as bis(fluorenyl)calcium or bis(fluorenyl)barium.

In another embodiment of the present invention, the latent activator material comprises an inorganic metal compound, which on thermal or optical activation releases the metal in its zero oxidation state. Non-limiting examples of such metals include Group I metals and Group II metals and the lanthanide series of metals. In one embodiment the activator material is of formula R₂M, wherein M is a metal and R is an azide (N₃). In some embodiments, M is a Group II metal such as but not limited to calcium, strontium, barium, and magnesium, or a lanthanide series of metal such as but not limited to lanthanum, cerium, europium, praseodymium and neodymium, or a Group I metal such as the alkali metals. Non-limiting examples of such inorganic compounds include barium bis azide of the formula Ba(N₃)₂. Preferably the metal has a work function of less than 3 eV. In a preferred embodiment, the metal compound is applied in solution to a base in atmospheric air. The base is preferably an electrode, an electrical conductor. The metal compound can also be an organometallic compound as discussed above.

In another embodiment, the OLED device has a cathode layer comprising a low work function metal or metal compound derived from at least one metal precursor capable of releasing the metal or metal compound when exposed to heat or light. Advantages of this combination are that a solution of the metal compound can be used to create the cathode layer in an ambient air atmosphere that does not require inerting of the work environment during manufacture.

The low work function metal or metal compound can have a work function value of less than 3.0 eV. The metal is selected from the group comprising Groups I, II, and the Lanthanide series of the periodic table.

In one embodiment the organic light emitting device (OLED) comprises:
a) a substrate,
b) at least one cathode layer covering at least part of one surface of the substrate, the cathode layer comprising at least one material selected from the group consisting of the elements of groups 1 and 2 and those of the Lanthanide group, and the material is formed by the deposition of a solution of the corresponding azide, (N₃)ₓ in atmospheric air, wherein ₓ has a value corresponding to the valence of the corresponding element, followed by the removal of at least a portion of the azide;
c) an anode layer material covering at least a portion of a second substrate; and
d) an organic light emitting material positioned between the cathode layer and the anode layer whereby light is emitted when opposing charges are applied to the anode and cathode layers.

The organic light emitting material is selected from the group comprising:

a) photoabsorption layer material or

b) an electroluminescent layer material, or,

c) an electrochromic material or

d) any combinations thereof and optionally;

e) a hole transport layer material,

f) a hole injection layer material,

g) an electron transport layer material,

h) an electron injection layer material, or

i) any combinations thereof.

In one embodiment, the cathode layer material comprises barium. In another embodiment the azide comprises barium bis azide of the formula Ba(N₃)₂.

In one embodiment of the present invention, the OLED is a light panel comprising:
a) a light panel substrate,
b) at least one continuous cathode layer covering at least 50% of one surface of the substrate, wherein the layer comprises at least one material selected from the group consisting of the elements of groups 1 and 2 and those of the Lanthanide group, and the material is formed by the deposition of a solution of the corresponding azide in atmospheric air followed by the removal of the azide;
c) an anode layer material; and
d) an organic light emitting material positioned between the cathode layer and the anode layer whereby light is emitted when opposing charges are applied to the anode and cathode layers.

In one embodiment, the organic light emitting material is selected from the group comprising:

e) photoabsorption layer material or

f) an electroluminescent layer material, or,

g) an electrochromic material or

h) any combinations thereof .

The light panel can further contain:

a) a hole transport layer material,

b) a hole injection layer material,

c) an electron transport layer material,

d) an electron injection layer material, or

e) any combinations thereof.

In one embodiment the light panel has a cathode layer material comprising barium and the corresponding barium bis azide has the formula Ba(N₃)₂.

In one embodiment the method of making an organic light emitting device comprises:

a) forming a cathode by applying a coating of a solution of at least one material selected from the group consisting of the azides of elements of groups 1 and 2 and those of the Lanthanide group to a substrate in atmospheric air,

b) removing the azide to form a coating of at least one material selected from the group comprising at least one of the elements of groups 1 and 2 and those of the Lanthanide group or a compound of at least one of the elements on the substrate to form the cathode. The azide can be barium bis azide of the formula Ba(N₃)₂.

In another embodiment the method of making an organic light emitting diode comprises the steps of:

a) selecting at least one precursor compound capable of transforming into a deposited, metal-containing layer;

b) forming a layer comprising the at least one unconverted precursor atop the substrate;

c) substantially fully converting the precursor layer so as to form a deposited, metal-containing cathode;

d) combining a light emitting organic layer with the cathode and;

e) combining an anode with the cathode and light emitting layer, the light emitting layer being positioned between the cathode and the anode.

The at least one precursor compound comprises a metal complex comprising: at least one ligand selected from the group consisting of azides and at least one metal selected from the group consisting of the metals of groups I and II and the Lanthanide group, and mixtures thereof.

The precursor can be barium bis azide of the formula Ba(N₃)₂. The converting can be accomplished using an energy source selected from the group consisting of light, heat, electron beam irradiation, ion beam irradiation, and mixtures thereof. The precursor compound can be applied as a fluid. The precursor layer formed on the substrate surface can comprise a mixture of a plurality of metal-organic precursor compounds. For improved efficiency the cathode has a work function value of less than 3.0 eV.

In all of the above OLEDs, the organic light emitting device may further include one or more layers such as a hole transport layer, a hole injection layer, an electron transport layer, an electron injection layer, an electroluminescent layer, a cathode layer or an anode layer or any combinations thereof. The OLED may further include a substrate layer such as but not limited to polymeric substrates.

In certain embodiments of the present invention, the organic light emitting device includes at least one latent activated layer being capable of spatially selective photo activation or thermal activation. Spatially selective activation enables patterning of the organic light emitting device. Non-limiting examples of thermal activation include placing the device with the latent activated layer on a hot plate or using a light source such as a laser source to selectively heat certain regions of the layer with the latent activated material. The heat energy absorbed by the latent activator material leads to the release of an activator material. Photo activation methods include but are not limited to irradiating the latent activator material using light sources such as but not limited to infrared, visible, ultraviolet light sources, including lasers. The latent activator material, upon absorption of light, is photo-initiated to release the activator material.

In certain other embodiments of the present invention, the organic light emitting device includes at least one latent counter activator material in contact with a activated region. By irradiating a latent activator material in contact with the activated region, to provide counter activators to neutralize the donors in the activated region, the activated region can be passivated. For example, by irradiating a latent photobase generator in contact with a p-activated region, electron donors will be released to neutralize the hole donors in the activated region. Spatially selective passivation can also enable patterning of the OLED device.

In accordance with another embodiment of the present invention, the organic light emitting device includes at least one activated layer, wherein the layer comprises photo or thermal activation products of at least one latent charge-donor material. Referring to FIG. 2, a second exemplary embodiment of a light emitting device 20 is illustrated. In the illustrated embodiment, the light emitting device 20 is shown to include a first electrode 22, an activated layer 24 with photo or thermal activation products of at least one latent activator material, an electroactive layer 26 and a second electrode 28. In some embodiments the activated organic electroactive layer is a light emitting polymer layer. In still another embodiment, the activated organic electroactive layer is a charge transport layer

The activated layer may further comprise a hole transport layer material, a hole injection layer material, an electron transport layer material, an electron injection layer material, a photoabsorption layer material, a cathode layer material, an anode layer material or an electroluminescent layer material, or any combinations thereof. The activated layer may include photo-activation products at more than one wavelength. The OLED may further include a substrate layer such as but not limited to polymeric substrates.

In some embodiments the activated layer comprises 100% by weight of the activator material. In certain other embodiments, the activator materials are present in a range from about 99% to 1% by weight of the activated layer. In other embodiments, the activator materials are present in a range from about 90% to about 20% of the activated layer composition. In still further embodiments the activator materials are present in a range from about 90% to about 50% of the activated layer. In some other embodiments the activator material may be present in a quantity as low as 100 parts per million of the total activated layer composition.

In some embodiments of the present invention, the organic light emitting device is patterned. The patterns may be regular, such as, but not limited to, alphabets, numerals and geometrical structures. The patterns may also be arbitrary and irregular. Patterning of the OLED device is enabled by photo or thermal induced spatially selective activation. Spatially selective activation is achieved using a pre-machined mask, negative film, or any other means.

In certain other embodiments of the present invention, patterning can also be achieved by spatially selective passivation. Selective passivation comprises de-activation by selectively irradiating a counter charge-donor material in contact with a activated region.

Referring to FIG. 3, another exemplary embodiment of a light emitting device 30 is illustrated. In the illustrated embodiment, the light emitting device 30 is shown to include a first electrode 32, a selectively activated electroactive layer 33 with activated regions 34 including photo or thermal activation products of at least one latent charge-donor material, and non-activated regions 36 with at least one latent activator material. The device further includes an additional organic electroactive layer 38 and a second electrode 40. In the selectively activated layer 33, only certain parts or sections of the layer are selectively activated, while certain sections are left either with the latent activator material or the regions could be deactivated or passivated. This selective activation enables patterning of the OLED. The patterning could include regular shapes, such as but not limited to alphabets or numbers or geometrical patterns or any combinations thereof and could also include arbitrary shapes and patterns.

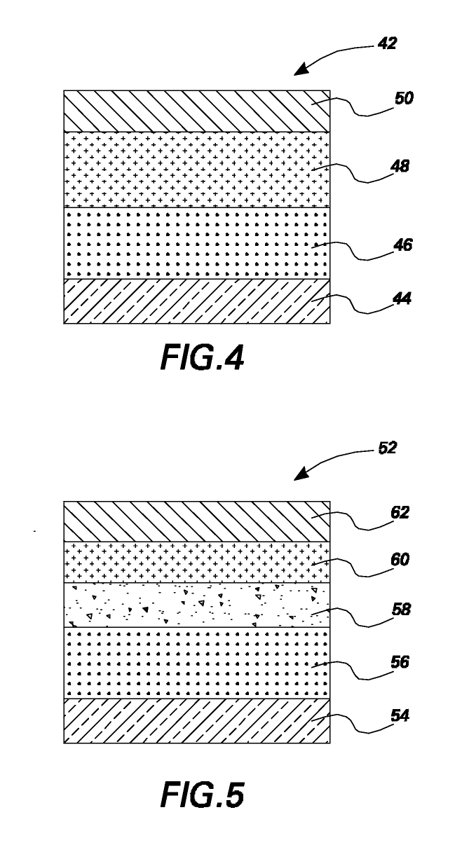

In the illustrated embodiment shown in FIG. 4, the light emitting device 42 includes a first electrode 44, a first activated layer 46 with photo or thermal activation products of at least one latent activator material, a second activated layer 48 with photo or thermal activation products of at least one latent activator material and a second electrode 50. In a non-limiting example the layer 46 is activated in such a way that it is able to inject and/or transport holes and the layer 48 is activated in such a way that it is able to inject and/or transport electrons.

Referring to FIG. 5, another exemplary embodiment of a light emitting device 52 is illustrated. In the illustrated embodiment, the light emitting device 52 is shown to include a first electrode 54, a first activated layer 56 with photo or thermal activation products of at least one latent charge-donor material and a second activated layer 60 with photo or thermal activation products of at least one latent charge-donor material. The device may further include an electroactive layer 58 between the two activated layers and a second electrode 62. In a non-limiting example the first electrode 54 is an anode and the second electrode 62 is a cathode.

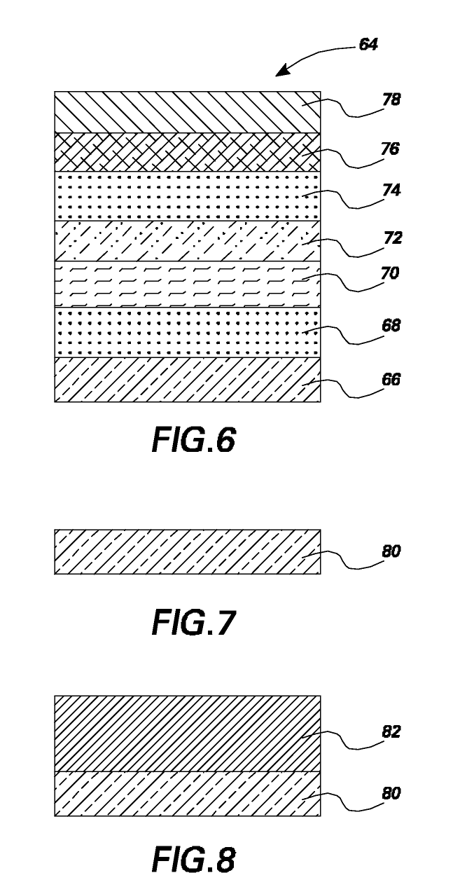

In the illustrated embodiment shown in FIG. 6, a tandem light emitting device 64 includes an anode 66, such as indium tin oxide (ITO), an activated electroactive layer 68 such as a hole injection layer with photo or thermal activation products of at least one latent charge-donor material, a light emitting polymer layer 70, a transparent cathode 72, a second activated hole injection layer 74 with photo or thermal activation products of at least one latent charge-donor material, a second electroactive layer 76 emitting at the same of different wavelength as the first light emitting layer and a cathode 78.

Non-limiting examples of charge transport layer materials include low-to-intermediate molecular weight (for example, less than about 200,000) organic molecules, poly(3,4-ethylenedioxythiophene) (PEDOT), polyaniline, poly(3,4-propylenedioxythiophene) (PProDOT), polystyrenesulfonate (PSS), polyvinyl carbazole (PVK), or like materials, or combinations thereof.

Non-limiting examples of hole transport layer materials include triaryldiamine, tetraphenyldiamine, aromatic tertiary amines, hydrazone derivatives, carbazole derivatives, triazole derivatives, imidazole derivatives, oxadiazole derivatives having an amino group, polythiophenes, and like materials. Suitable materials for a hole blocking layer comprise poly(N-vinyl carbazole), and like materials.

Non-limiting examples of hole injection enhancement layer materials include arylene-based compounds such as 3,4,9,10-perylenetetra-carboxylic dianhydride, bis(1,2,5-thiadiazolo)-p-quinobis(1,3-dithiole), and like materials.

Materials suitable for the electron injection enhancement layer materials and electron transport layer materials include metal organic complexes such as oxadiazole derivatives, perylene derivatives, pyridine derivatives, pyrimidine derivatives, quinoline derivatives, quinoxaline derivatives, diphenylquinone derivatives, nitro-substituted fluorene derivatives, and like materials.

Non-limiting examples of materials which may be used in light emitting layers include poly(N-vinylcarbazole) (PVK) and its derivatives; polyfluorene and its derivatives such as poly(alkylfluorene), for example poly(9,9-dihexylfluorene), poly(dioctylfluorene) or polyl{9,9-bis(3,6-dioxaheptyl)-fluorene-2,7-diyl}, poly(para-phenylene) (PPP) and its derivatives such as poly(2-decyloxy- 1,4-phenylene) or poly(2,5-diheptyl-1,4-phenylene); poly(p-phenylene vinylene) (PPV) and its derivatives such as dialkoxy-substituted PPV and cyano-substituted PPV; polythiophene and its derivatives such as poly(3-alkylthiophene), poly(4,4′-dialkyl-2,2′-bithiophene), poly(2,5-thienylene vinylene); poly(pyridine vinylene) and its derivatives; polyquinoxaline and its derivatives; and polyquinoline and its derivatives. In one particular embodiment a suitable light emitting material is poly(9,9-dioctylfluorenyl-2,7-diyl) end capped with N,N-bis(4-methylphenyl)-4-aniline. Mixtures of these polymers or copolymers based on one or more of these polymers and others may also be used.

Another class of suitable materials used in light emitting layers are polysilanes. Typically, polysilanes are linear silicon-backbone polymers substituted with a variety of alkyl and/or aryl side groups. They are quasi one-dimensional materials with delocalized sigma-conjugated electrons along polymer backbone chains. Examples of polysilanes comprise poly(di-n-butylsilane), poly(di-n-pentylsilane), poly(di-n-hexylsilane), poly(methylphenylsilane), and poly{bis(p-butylphenyl)silane }.

Suitable cathode materials for electroactive devices typically include materials having low work function value. Non-limiting examples of cathode materials include materials such as K, Li, Na, Mg, Ca, Sr, Ba, Al, Ag, Au, In, Sn, Zn, Zr, Sc, Y, Mn, Pb, elements of the lanthanide series, alloys thereof, particularly Ag—Mg alloy, Al—Li alloy, In—Mg alloy, Al—Ca alloy, and Li—Al alloy and mixtures thereof. Other examples of cathode materials may include alkali metal fluorides, or alkaline earth fluorides, or mixtures of fluorides. Other cathode materials such as indium tin oxide, tin oxide, indium oxide, zinc oxide, indium zinc oxide, zinc indium tin oxide, antimony oxide, carbon nanotubes, and mixtures thereof are also suitable. Alternatively, the cathode can be made of two layers to enhance electron injection. Non-limiting examples include, but are not limited to, an inner layer of either LiF or NaF followed by an outer layer of aluminum or silver, or an inner layer of calcium followed by an outer layer of aluminum or silver.

Suitable anode materials for electroactive devices typically include those having a high work function value. Non-limiting examples of anode materials include, but are not limited to, indium tin oxide (ITO), tin oxide, indium oxide, zinc oxide, indium zinc oxide, nickel, gold, and like materials, and mixtures thereof.

Non limiting examples of substrates include thermoplastic polymer, poly(ethylene terephthalate), poly(ethylene naphthalate), polyethersulfone, polycarbonate, polyimide, acrylate, polyolefin, glass, metal, and like materials, and combinations thereof.

Organic light emitting devices of the present invention may include additional layers such as, but not limited to, one or more of an abrasion resistant layer, an adhesion layer, a chemically resistant layer, a photoluminescent layer, a radiation-absorbing layer, a radiation reflective layer, a barrier layer, a planarizing layer, optical diffusing layer, and combinations thereof.

In still another embodiment of the present invention is method of making an organic light emitting device, as will be described further below with reference to FIGS. 7-24. The method generally includes providing a substrate and disposing at least one organic device layer over the substrate, wherein the layer comprises one or more latent activator materials. The substrate is typically an electrode. The electrode substrate may also include other substrates such as but not limited to polymeric substrates.

The method further includes the step of generating a base or an acid by photo-activation or thermal-activation of the latent activator material. Activation may be performed at any step during the fabrication of the organic light emitting device. Activation may also be performed after the device has been assembled, at anytime during the life of the device. The method may further include the step of patterning or spatially selective activation. The patterning may be regular such as but not limited to alphabets, numerals and geometrical structures. The patterning may also be arbitrary and irregular. Spatially selective activation is achieved using a pre-machined mask, negative film, or any other means. Activation may include photo-activation of one or more latent charge-donor materials at one or more wavelengths.

In some embodiments the method may further include the step of spatially selective passivation, wherein spatially selective passivation comprises irradiating a latent counter activator material in contact with a activated region. For example, a p-activated layer may be selectively passivated or de-activated by irradiating a photobase-generator in contact with the p-activated layer. Patterning of the OLED can also be achieved by spatially selective passivation.

The method may further comprise disposing over the substrate a hole transport layer material, a hole injection layer material, an electron transport layer material, an electron injection layer material, a photoabsorption layer material, a cathode layer material, an anode layer material or an electroluminescent layer material, or any combinations thereof. In some embodiments, the method may further include laminating together layers, with at least one layer including a latent activator material or activation products of a latent activator material.

In some embodiments, the latent activator material is deposited in combination with other OLED layer materials. For example, a latent activator material may be deposited in combination with a light emitting layer material. In other embodiments, the latent activator material is deposited on top of an OLED layer. Upon activation, the activator material released, surface modifies the underlying layer.

The method of depositing or disposing a layer comprises techniques such as but not limited to spin coating, dip coating, reverse roll coating, wire-wound or Mayer rod coating, direct and offset gravure coating, slot die coating, blade coating, hot melt coating, curtain coating, knife over roll coating, extrusion, air knife coating, spray, rotary screen coating, multilayer slide coating, coextrusion, meniscus coating, comma and microgravure coating, lithographic process, Langmuir process and flash evaporation, vapor deposition, plasma-enhanced chemical-vapor deposition (“PECVD”), radio-frequency plasma-enhanced chemical-vapor deposition (“RFPECVD”), expanding thermal-plasma chemical-vapor deposition (“ETPCVD”), sputtering including, but not limited to, reactive sputtering, electron-cyclotron-resonance plasma-enhanced chemical-vapor deposition (ECRPECVD”), inductively coupled plasma-enhanced chemical-vapor deposition (“ICPECVD”), and like techniques, and combinations thereof.

FIGS. 7-22 are cross-sectional representations of exemplary processes of fabricating organic light emitting devices illustrated in FIGS. 1-6, according to aspects of the present technique. An electrode 80, as illustrated in FIG. 7, is used as a substrate to deposit subsequent layers. An example of an electrode is an ITO anode. In certain embodiments, the electrode may further include a polymeric substrate. The electrode may be subject to UV/ozone surface treatment prior to deposition of subsequent layers. As used herein, device sub-structures may include one or more substrate layers, one or more electrode layers, one or more latent activated layers, one or more activated layers, one or more electroactive layers, or one or more additional layers such as but not limited to adhesion layers, and barrier layers. In some embodiments, two or more device sub-structures may be deposited or disposed over each other to form the organic light emitting devices. In further embodiments, two or more device sub-structures may be combined to form an organic light emitting device using processes such as but not limited to lamination.

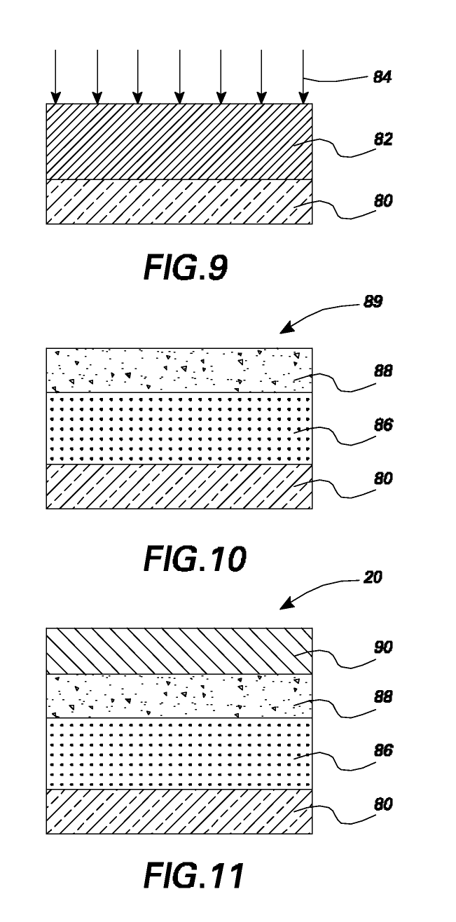

As shown in FIG. 8, a latent activated electroactive layer 82 with a latent activator material is deposited over the electrode. The latent activated electroactive layer 82 may be an organic electroactive layer and may further include, for example, a hole transport material or a light emitting material. As shown in FIG. 9, the latent activated electroactive layer 82 including latent activator material is then activated by the application of heat or light, and thermal or photoactivation respectively, as indicated by reference numeral 84. The activation of the latent activated electroative layer 82 results in an activated electroactive layer 86 as shown in FIG. 10 to form a device sub-structure 89. Other layers may be deposited over the sub-structure to form the light emitting device. The process may proceed further with the deposition of at least one more electroactive organic layer 88. Finally, as shown in FIG. 11, a second electrode 90, such as a cathode layer, may be deposited over the electroactive layer 88 to form a light emitting device 20 (see FIG. 2).

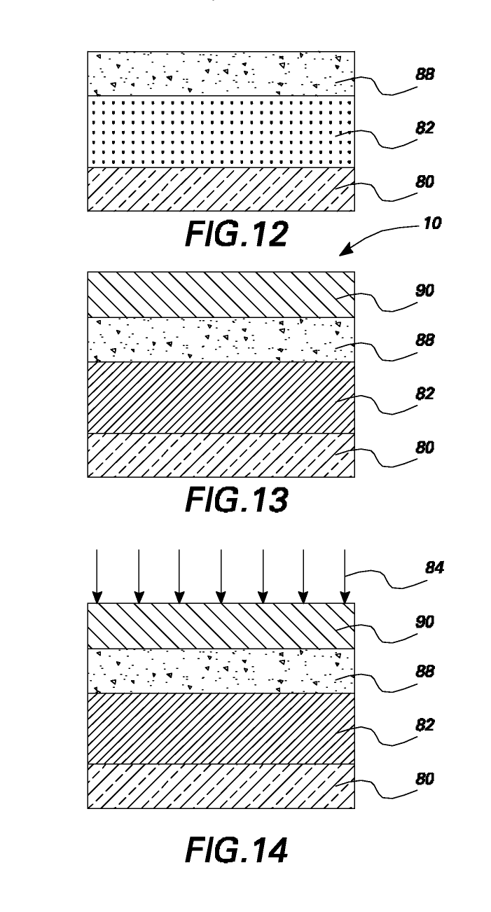

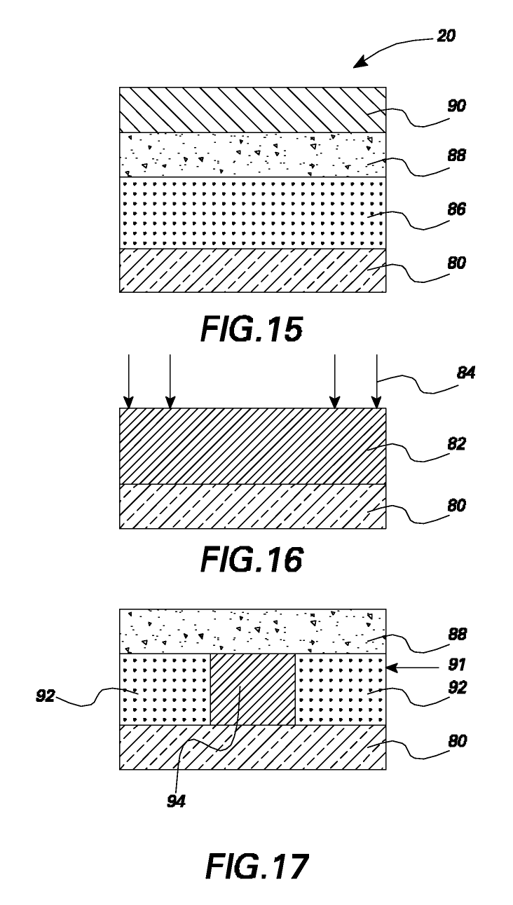

Alternatively the process may proceed from the process step shown in FIG. 8 to the process step shown in FIG. 12, where an electroactive layer 88 is deposited over the latent activated electroactive layer 82. The device 10 (see FIG. 1) is completed on disposing an electrode 90 over the electroactive layer 82. The latent activated electroactive layer 82 may be subsequently activated by the application of thermal or photoactivation 84 resulting in the formation of an activated layer 86 and the device 20, as shown in FIG. 15.

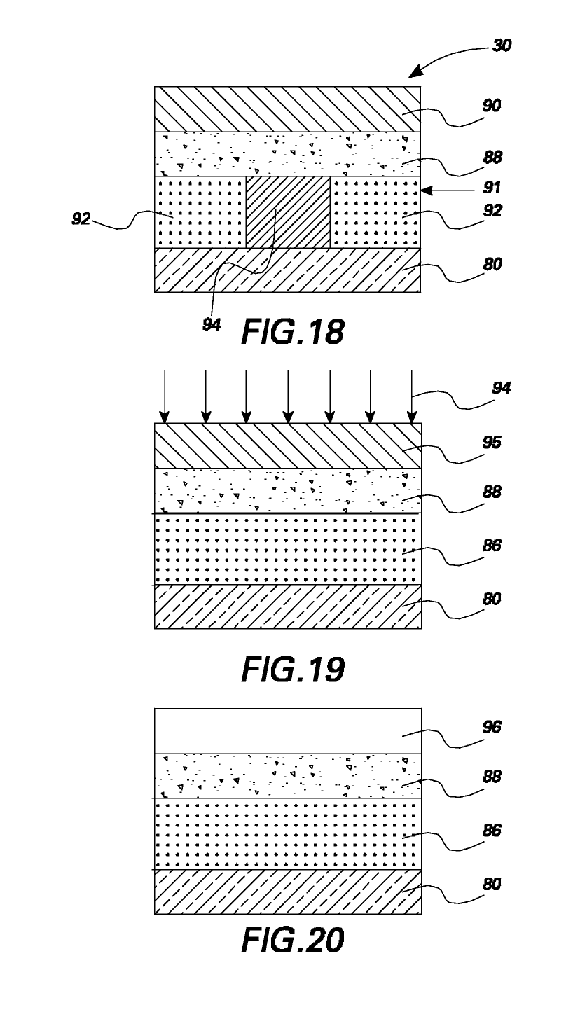

In another alternate process path, the process may proceed from the process step shown in FIG. 8 to the process step shown in FIG. 16, where the electroactive layer 82 may be selectively activated. Selective activation can result in the patterning of the OLED device. Patterning can be desirably regular or arbitrary. Selective activation results in a patterned layer 91, with activated regions 92 with activator material and still latent activated regions 94 as shown in FIG. 17. Additional layers such as an electroactive layer 88 and an electrode layer 90 may be deposited to fabricate the light emitting device 30 as shown in FIG. 18.

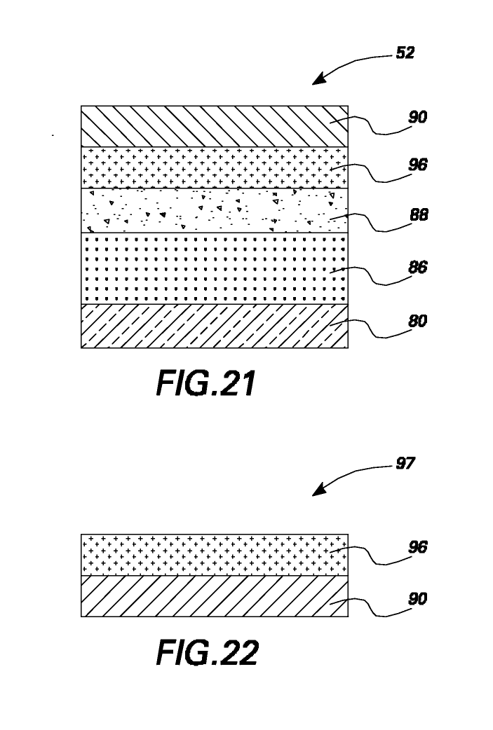

Alternatively, the process may proceed from the process step shown in FIG. 12 to the process step shown in FIG. 19, where a second latent activated layer 95 may be deposited over the electroactive layer 88. The latent activated layer 95 is subjected to photo or thermal activation 94 to give a second activated layer 96 as shown in FIG. 20. As shown in FIG. 21 a second electrode may be disposed over the second activated layer 96 resulting in the device 52. In a non-limiting example, the first activated layer 86 is a p-activated layer and the second activated layer 96 is an n-activated layer.

Alternatively, the process which includes the process step shown in FIG. 10, where a first device sub-structure 89, including an electrode 80, a first activated layer 86 and an additional electroactive layer 88, is formed, may also include the process step shown in FIG. 22, where a second device sub-structure 97 including an activated layer 96 and a second electrode substrate layer 90 is formed. The activated layer 96 may be formed by activating a latent activated layer, such as layer 95, shown in FIG. 19. Following the process steps to make the first and second device sub-structures, 89 and 97, the two sub structures may be laminated together to form a device 52, as shown in FIG. 21. In some embodiments, lamination is carried out by bringing together the first device sub-structure and the second device sub-structure, and applying one of pressure or heat or combinations thereof to the substructures. In one embodiment, the first device sub-structure 89, and the second device sub-structure 97, are overlaid and guided through a roll laminator to form the device 52. In some embodiments, lamination is performed at a temperature of 150° C. In certain embodiments, activation of latent activator materials in a sub-structure may occur prior to lamination as shown in FIGS. 10 and 19. In other embodiments, activation of the latent of latent activator materials in a sub-structure may occur subsequent to lamination, such that at the time of lamination, the first and/or second device structures may include latent activated layers. In a non-limiting example, first and second device substructures may include one or more substrate layers, one or more electrodes, one or more latent activated layers, one or more activated layers, one or more electroactive layers, or one or more other layers such as but not limited to adhesion layers, and barrier layers.

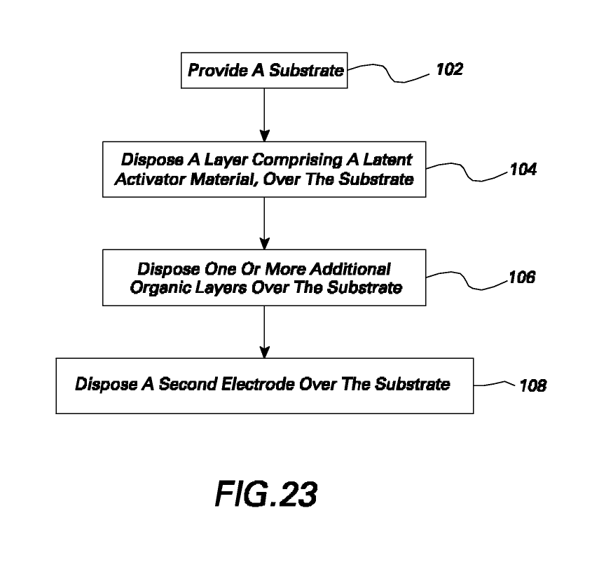

FIG. 23 is a flow chart illustrating an exemplary process 100 of fabricating an organic light emitting device according to aspects of the present technique as. The process 100 includes the step of providing a substrate 102 (see FIG. 7), which may be an electrode, for example, disposing a layer comprising a latent activator material over the substrate 104 (see FIG. 8), disposing one or more additional organic layers over the substrate 106 (see FIG. 12), and then disposing a second electrode over the substrate 108 (see FIG. 13).

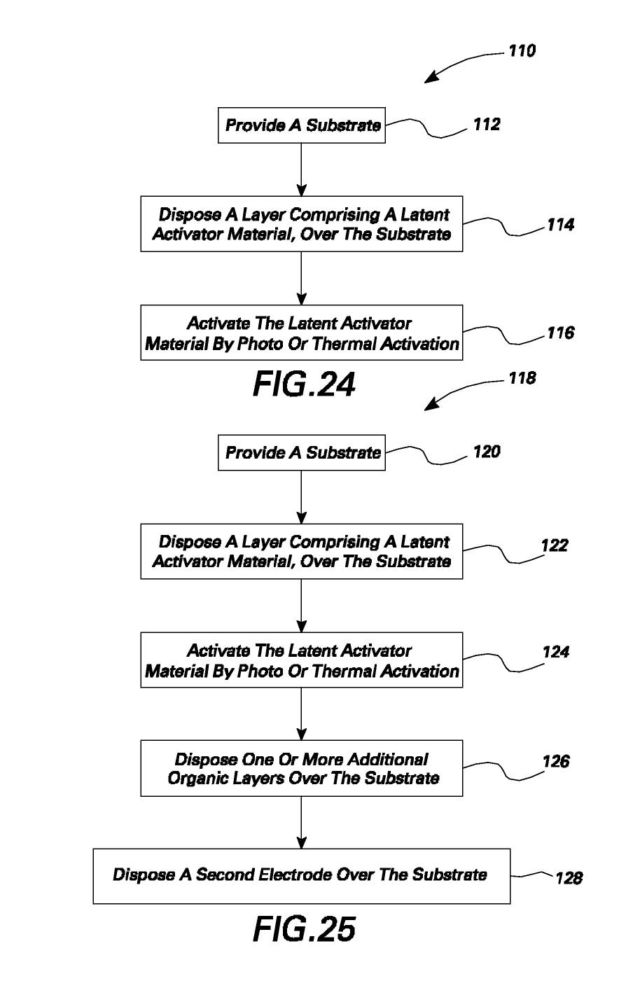

FIG. 24 is a flow chart illustrating an exemplary process 110 of fabricating a organic light emitting device according to aspects of the present technique. Process 110 begins with step 112, where a substrate, which may be an electrode, for example, is provided (see FIG. 7). The process 110 proceeds with step 114 of disposing a layer comprising a latent activator material over the substrate (see FIG. 8). In step 116, the process proceeds to activate the activator material by photo or thermal activation (see FIG. 9).

FIG. 25 is a flow chart illustrating an exemplary process 118 of fabricating the organic light emitting device according to aspects of the present technique. In step 120 of process 118 a substrate, which may be an electrode, for example, is provided (see FIG. 7). The process 118 proceeds with step 122 of disposing a layer comprising a latent activator material over the substrate (see FIG. 8). In step 124, the process proceeds to activate the activator material by photo or thermal activation (see FIG. 9), followed by the step of disposing one or more additional organic layers over the substrate 126 (see FIG. 10) and finally step 128, where a second electrode is disposed over the substrate (see FIG. 11).

Without further elaboration, it is believed that one skilled in the art can, using the description herein, utilize the present invention to its fullest extent. The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

Kelvin probe (KP) is a vibrating capacitor technique used to measure change in the effective surface work function of conducting/semi-conducting materials by measuring contact potential differences (CPDs, which correspond to changes in effective surface work functions) in units of volts relative to a common probe. KP measurements were conducted with a digital Kelvin probe KP6500.

### EXAMPLE 1

A thiophene-based conducting polymer, poly(3,4-ethylenedioxythiophene) tetramethacrylate end-capped (PEDOT-TMA) obtained from Aldrich as a 0.5 wt % dispersion in propylene carbonate, was used in this example. An iodonium salt diphenyliodonium hexafluorophosphate, Ph₂IPF₆, obtained from Aldrich was used as the latent activator material. A mixture solution (referred to as PEDOT-TMA:Ph₂IPF₆) of PEDOT-TMA and Ph₂IPF₆ was prepared by mixing 2 gram PEDOT-TMA in propylene carbonate with 100 milligram Ph₂IPF₆ in 1.5 milliliter propylene carbonate.

TABLE 1
Experimental results of Kelvin probe (KP) measurements of contact
potential difference (CPD)

| | | CPD | |
|---|---|---|---|
| | | Average of 20 | Standard |
| Sample | Sample structures | data points | deviation |
| Sample 1 | ITO (as cleaned) | −0.275 | 0.007 |
| Sample 2 | ITO/PEDOT-TMA (as spin-coated) | −0.247 | 0.006 |
| Activated | ITO/PEDOT-TMA (UV-ozoned 5minutes) | −0.304 | 0.007 |
| Sample 2 | | | |
| Sample 3 | ITO/PEDOT-TMA:Ph₂IPF₆ (as spin-coated) | −0.271 | 0.007 |
| Activated | ITO/PEDOT-TMA:Ph₂IPF₆ (UV-ozoned | −1.293 | 0.005 |
| Sample 3 | 5 minutes) | | |

Three samples (Table 1) for the KP measurements were prepared as follows. Indium tin oxide (ITO, about 140 nanometer) coated glass obtained from Applied Films Corporation was used as a conductive substrate. Sample 1 was bare pre-cleaned ITO, Sample 2 consisted of ITO and a layer (about 40 nanometer) of PEDOT-TMA that was applied via spin-coating from its solution in propylene carbonate at a spin-speed of 4000 rpm, Sample 3 consisted of ITO and a layer (about 35 nanometer) of PEDOT-TMA:Ph₂IPF₆ that was applied via spin-coating from the mixture solution at a spin-speed of 4000 rpm. KP measurements were then conducted on the samples prior to and post a ultra-violet ozone treatment. Both the UV-ozone treatment and the KP measurements (with a Ultraviolet Ozone Cleaner, Model 42, obtained from the Jelight Company, Irvine, Calif. 92618, U.S.A.) were conducted in the ambient environment with a room temperature of about 24° C. and a relative humidity of about 64%.

It be seen from the results listed in Table 1, introducing PEDOT-TMA did not cause significant changes in CPD (and equivalently, the effective work function) of the ITO substrate, regardless of whether the PEDOT-TMA was UV-ozone treated (Activated Sample 2) or not (Sample 2). Similarly, the presence of PEDOT-TMA:Ph₂IPF₆, as spin-coated (Sample 3) did not significantly alter the measured CPD. However, a significant reduction in CPD (equivalently, increase in effective work function) was observed after the PEDOT-TMA:Ph₂IPF₆ mixture layer was UV-ozone treated.

### EXAMPLE 2

devices were fabricated. The OLEDs consisted of a blue light-emitting polymer (LEP), ADS329BE [poly(9,9-dioctylfluoenyl-2,7-diyl)—end capped with N,N-Bis(4-methylphenyl)-aniline], obtained from American Dye Sources, Inc, Canada, and used as received without any further purification, as the emissive layer material.

s were fabricated as follows. ITO coated glass, patterned using standard photolithography techniques, was used as the anode substrate. The OLEDs employ an ITO anode with and without an additional anode-activation layer but otherwise the same structure. As shown in the Table 2, both device A and device B had the same ITO anode except that the ITO substrate in device B was further UV-ozoned for 5 minutes prior to the application of ADS329BE. Devices C and D had the same anode-activation layer of PEDOT-TMA (about 40 to 45 nanometer) except that the PEDOT-TMA layer in the device D was further UV-ozoned for about 5 minutes prior to the application of ADS329BE. Both device E and F had the same anode-activation layer (about 35 nanometer) of PEDOT-TMA:Ph₂IPF₆ except that the PEDOT-TMA:Ph₂IPF₆ layer in the device F was further UV-ozoned for about 5 minutes prior to the application of ADS329BE. Next, a layer (65±3 nanometer) of ADS329BE was spin-coated from its solution (1.7 wt %) in p-xylene atop of the ITO with and without the anode-activation layers. Application of the anode-activation layers and the ADS329BE layer as well as UV-ozone treatments were all conducted in the ambient environment with a room temperature of 24° C. and a relative humidity of 64%. Then the samples were transferred into a glovebox filled with Argon (moisture and oxygen was less than about 1 ppm and about 10 ppm, respectively). Next, a NaF(4 nanometer)/A1 (110 nanometer) bilayer cathode was then thermally-evaporated atop of the ADS329 emissive layer. After metallization (metallization refers to disposing metal layers such as aluminum to electrically connect or interconnect various device structures), the devices were encapsulated with a cover glass sealed with an optical adhesive Norland 68 obtained from Norland products, Inc, Cranbury, N.J. 08512, USA. The active area was about 0.2 cm².

TABLE 2
Measured performance charcteristics of the OLED Devices

| | | | At a fixed current density | | |
|---|---|---|---|---|---|
| | | Turn-on | of 10 mA/cm² | | |
| | Anode/Anode-activation | voltage | Voltage | Efficiency | |
| Device | layer | (Volts) | (Volts) | cd/A | lm/w |
| Device A | ITO (as cleaned) | >12.0 | 9.1 | 0.00012 | 0.000042 |
| Device B | ITO (UV-ozoned 5 minutes) | 10.1 | 9.1 | 0.002 | 0.00077 |
| Device C | ITO/PEDOT-TMA (as a spin-coated) | >12.0 | 8.4 | 0.00026 | 0.000098 |
| Device D | ITO/PEDOT-TMA (UV- | 7.4 | 7.2 | 0.0078 | 0.0034 |
| | ozoned 5 mins) | | | | |
| Device E | ITO/PEDOT-TMA: Ph₂IPF₆ | 7.8 | 7.4 | 0.005 | 0.0020 |
| | (as spin-coated) | | | | |
| Device F | ITO/PEDOT-TMA: Ph₂IPF₆ | 3.5 | 4.6 | 0.4 | 0.27 |
| | (UV-ozoned 5 minutes) | | | | |

Measured performance characteristics of the devices is summarized in Table 2. It can be seen that the use of UV-ozone treated PEDOT-TMA:Ph₂IPF₆ anode-activation layer yielded an OLED device with significantly enhanced efficiency and much-lowered turn-on voltage (defined as the applied voltage when the corresponding brightness has reached 1 cd/m2) relative to the devices having either a bare ITO anode or with the PEDOT-TMA anode-activation layer. Since all devices share the same type of emissive layer as well as the same type of bilayer cathode, the enhancement in performance can be attributed to the fact that the ITO electrode had been activated by the PEDOT-TMA: Ph₂IPF₆, leading to much enhanced hole-injection. The measured performance characteristics indicate that the presence of Ph₂IPF₆ and the UV-ozone treatment are the key factors contributing to the observed activation effect.

Although the applicants do not wish to be bound by any particular theory, it is believed that upon UV irradiation (and/or other latent means), Ph₂IPF₆, widely known as a photoacid generator, decomposes and generates a strong acid (HPF₆) and the (photo)-generated acid is able to activate the PEDOT-TMA host and most likely the PEDOT-TMA:Ph₂IPF₆/LEP interface as well, thus resulting in much enhanced hole-injection from the ITO electrode into the active LEP layer and, subsequently, the overall performance

### EXAMPLE 3

A 2 liter, 3-neck flask was charged with Adogen 464 (about 23 grams), 2-bromo-propane (about 235 milliliter), potassium hydroxide (saturated, aq, about 1.2 liter), and freshly cracked and distilled cyclopentadiene (41 milliliter). The contents were stirred with a mechanical stirrer and heated to about 80° C. for 24 hours. Gas chromatography analysis of the top layer showed excellent conversion to tetra-iso-propylcyclopentadiene. The entire reaction mixture was poured into a separatory funnel. Addition of water and hexanes broke up the emulsion and the top layer was collected. The bottom aqueous layer was washed with hexanes, and a total of about 1.5 liter of organic solvents was collected. The organic layer was then dried with magnesium sulfate and then filtered and washed with more hexanes. The total organics were then subjected to rotary evaporation (30 mmHg) and 80° C. to remove hexanes and leave a higher boiling oil. The oil was then subjected to vacuum distillation through a Vigreaux column, 0.6 mmHg. Fractions that boiled between 110-130° C. were collected (about 53.1 grams). The entire distillate was dissolved in dry tetrahydrofuran (THF) (about 500 milliliter) and then potassium (about 10 grams) was slowly added and gas evolution was noted. The contents were stirred for 17 hours. The reaction was quenched by addition of water. The contents were extracted with hexanes, dried with magnesium sulfate and then the hexanes were removed in vacuo. The recovered oil was placed in the refrigerator to give colorless crystals, C₅H₂(i-propyl)₄.

C₅H₂(i-propyl)₄, as prepared above (about 8.12 grams) was combined with THF (about 100 milliliter) and potassium hydride (about 1.4 grams) and stirred for about 24 hours. The solution was filtered under nitrogen and washed with dry THF under nitrogen to give a white solid, tetra-i-propyl-cyclopentadienyl potassium (K[HC₅(i-propyl)₄]). K[HC₅(i-propyl)₄] (about 2.81 gram) was combined with barium iodide (about 2 gram) in THF (50 milliliter) and stirred for about 24 hours under nitrogen. The solution was filtered under nitrogen to remove potassium iodide and the solid was washed with THF. The THF was removed in vacuo to give a solid that contained Bis(tetra-i-propyl-cyclopentadienyl)barium (Ba-TPCP).

About 55.7 milligram Ba-TPCP was dissolved in about 11 milliliter of xylenes to prepare a solution with a nominal concentration of about 0.5 wt %. The solution was prepared in the glovebox filled with argon (moisture and oxygen was less than about 1 parts per million (ppm) and about 3 ppm, respectively). The solution, as prepared, had some undissolved material(s) precipitated on the bottom of the glass vial. The top clear solution was taken and used without any filtration steps.

Three samples, Sample 4, Sample 5 and Sample 6 were prepared for KP measurements. For all samples, a layer (about 80 nm) of Al, used as a conductive substrate, was initially thermally evaporated over a pre-cleaned glass slide.

KP measurements on Sample 4 were conducted on the Al substrate prior to and post exposure to the ambient environment (referred to as “air exposure”) and baking. The ambient environment refers to normal room conditions with a temperature of about 24° C. and relative humidity of about 62% when the experiments were conducted. For Sample 5, the solution of Ba-TPCP was spin-coated on top of the Al in the same glovebox. A series of KP measurements were then conducted on Sample 5, (1) as spin-coated, (2) after a step air exposure for 3mins, (3) after a step of baking at about 180° C. for about 15 minutes in the glovebox, (4) after another air exposure for 3 minutes, (5) after another step of baking at about 180° C. for about 15 minutes in the same glovebox and (6) after another air exposure for about 3 minutes. For Sample 6, the solution of Ba-TPCP was spin-coated over the Al in the glovebox. A series of KP measurements were then conducted on Sample 6 (1) as spin-coated, (2) after a step of baking at about 180° C. for about 15 minutes in the same glovebox, (3) after air exposure for about 3 minutes.

Results of KP measurements are summarized in Table 3. Measurements indicate that the baking step in the glovebox is critical. The increase in CPD in response to the baking step (or the 1^{st} baking step as for the sample A) corresponds to a significant reduction in effective work function.

TABLE 3
Experimental results of Kelvin probe (KP) measurements of contact
potential difference (CPD) on Al with and without the Ba-TPCP layer

| | | CPD | |
|---|---|---|---|
| | | average of 20 | standard |
| | Treatment | data points | deviation |
| SAMPLE 4 | As prepared | 1.372 | 0.006 |
| Al substrate | | | |
| | Air exposure (3 | 1.369 | 0.006 |
| | minutes) | | |
| | Baked at 180° C. for 15 | 1.371 | 0.007 |
| | minutes | | |
| SAMPLE 5 | As spin-coated | 1.357 | 0.007 |
| Al/Ba-TPCP | | | |
| | Air exposure (3 | 1.175 | 0.005 |
| | minutes) | | |
| | Baked at 180° C. for 15 | 1.456 | 0.007 |
| | minutes in the glovebox | | |
| | Air exposure (3 | 1.055 | 0.007 |
| | minutes) | | |
| | Baked at 180° C. for 15 | 1.123 | 0.005 |
| | minutes in the glovebox | | |
| | Air exposure (3 | 1.078 | 0.007 |
| | minutes) | | |
| SAMPLE 6 | as spin-coated | 1.351 | 0.006 |
| Al/Ba-TPCP | | | |
| | Baked at 180° C. for 15 | 1.545 | 0.007 |
| | minutes in the glovebox | | |
| | Air exposure (3 | 1.013 | 0.007 |
| | minutes) | | |

### EXAMPLE 4

Four OLED devices were fabricated. Two solutions were prepared in the same glovebox (moisture and oxygen was less than 1 ppm and 3 ppm, respectively) prior to device fabrication. The first solution (referred to OAP9903:SR454) included a green light-emitting polymer poly[(9,9-dioctylfluoren-2,7-diyl)-alt-co-(benzo[2,1,3]thiadiazol-4,7-diyl)] (OPA9903) obtained from H. W. Sands, Corporation, Jupiter, Fla. 33477, USA and an acrylate-based adhesive ethoxylated (3) trimethylolpropane triacrylate (SR454) obtained from Sartomer, Exton, Pa. 19341, USA. Both materials were used as received without any further purification. The mixture solution was prepared by mixing about 2.5 milliliter of a 2% OPA9903 solution in p-xylene with about 2 milliliter of a 1% SR454 solution in p-xylene. The resulting ratio of SR454 to OPA9903 was about 30 wt %. The second solution (referred to as OPA9903:Ba-TPCP) including OPA9903 and Ba-TPCP was prepared by mixing about 1.5 milliliter of a 0.6 wt % OPA9903 solution in xylenes with about 3 milliliter of the Ba-TPCP solution in xylenes.

OLEDs were fabricated as follows. Pre-patterned ITO coated glass used as the anode substrate was cleaned with UV-ozone for 10 mins. Then a layer (60 nm) of [poly(3,4)-ethylindioxythiophene/polystrene sulfonate] (PEDOT/PSS) polymer obtained from Bayer Corporation was deposited atop the ITO via spin-coating and then baked for 1 hour at 180° C. in the ambient environment (with a room temperature of 24° C. and a relative humidity of 62%). Then the samples were transferred to the same glovebox. The following steps, unless further specified, were carried out in the same glovebox. Next, the emissive layer consisting of OPA9903:SR454 was spin-coated from its solution in p-xylene atop the PEDOT/PSS layer and then cured with a UV lamp (R-52 grid lamp, obtained from Ultroviolet Products, Upland, Calif., 91796, U.S.A. with the filter removed) (the intensity measured at about 310 nm, 365 nm and 400 nm was 0.39, 0.43 and 1.93 mW/cm²) for 1 minute. Next, a layer of the mixture of OPA9903:Ba-TPCP was spin-coated atop the cured emissive layer and then baked at about 180° C. for about 15 minutes. Finally, a layer (about 110 nanometer) of Al was then thermally evaporated through a shadow mask atop of the OPA9903:Ba-TPCP layer. Following metal evaporation, the devices were encapsulated using a glass slide sealed with the optical adhesive Norland 68. The active area is about 0.2 cm².

Four OLED devices were made. Control device, device G, did not have the mixture layer of OPA9903:Ba-TPCP. Devices H, I and J had the same structure except that the mixture layer of OPA9903:Ba-TPCP was treated differently prior to the Al deposition. For device H, the mixture layer, as spin-coated, was exposed to the ambient environment for about 3 minutes, then baked at 180° C. for about 15 minutes in the same glovebox. For device I, the mixture layer was not exposed to the ambient environment, and for the device J, the mixture layer was exposed to the ambient environment for 3 minutes after the baking step. FIG. 25 shows the efficiency (measured in candela per ampere, cd/A) versus current density (measured in milliamperes per square centimeter, mA/cm²) for devices G, H, J, and I.

Comparison of the efficiency 130 versus current density 132 curves indicates that introducing the mixture layer of OPA9903:Ba-TPCP as in the device H (curve 136), I (curve 140) and J (curve 138) significantly improves the device efficiency relative to the control device G (curve 134). Since all four devices share the same anode, it is believed that the observed improvement in efficiency directly reflects the activation of the bare Al cathode. Furthermore, the plots also indicate that the sequence of baking and exposure to ambient environment is important. The device I without any exposure to ambient the environment showed the greatest improvement relative to the device H and the device J. The device H that was exposed to the ambient environment prior to the baking step shows better efficiency relative to the device J that was exposed to the ambient environment post the baking step.

Although the Applicants do not wish to be bound by any particular theory, it is believed that upon baking (and/or other latent means) the barium compound (Ba-TPCP) decomposes and releases free barium atoms that are able to, subsequently, activate the active polymer (OPA9903). Equation 5, shows an alkaline earth metal organometallic compound M-TPCP, where M is any alkaline earth metal including barium, decomposing on application of heat to release the free metal atoms. 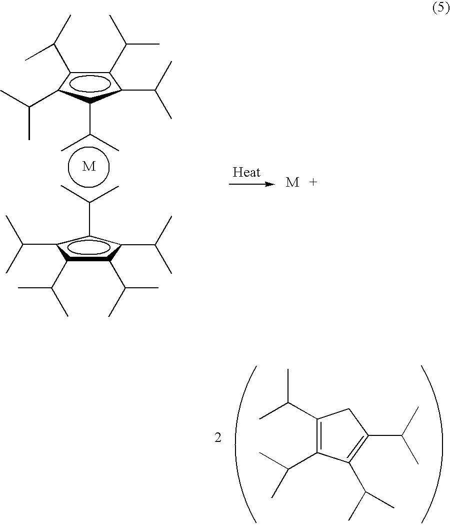
The activated OPA9903 facilitates the electron injection from the bare Al cathode into the active layer of OPA9903.

### EXAMPLE 5

The following data shows that an air-deposited aqueous solution of barium azide Ba(N₃)₂ on aluminum glass (Al/glass), then activated in an inert atmosphere from 150-200° C., leads to a surface with a work function lowered by over 0.5V.

The example was performed by measuring the contact potential difference (CPD) of the Al/glass surface in the Kelvin probe in air followed by spin coating various solutions of barium azide onto the Al/glass surface. Samples were heated on a hot plate in the gJove box, loaded into the Kelvin probe in the glove box and CPD value obtained. Samples were exposed to air after activation and the CPD value re-measured.

Ba(N₃)₂ was obtained as an aqueous solution from Pfaltz & Bauer with obvious Ba(N₃)₂ crystals on the bottom of the bottle, Given the presence of crystals it is assumed that the solution was saturated and thus was at the CRC reported value, 17.3 g Ba(N₃)₂/100 g water at 17C, 078 mole/L. Al/glass had CPD values of about 1 V when loaded in the Kelvin probe in the glove box, 0₂ level ca. 5 ppm. After air exposure the work function of Al/glass increased 0.1-0.15 V All samples spin coated in air at 4000 rpm and heated 200^{N} C for 10 minutes unless noted otherwise.

In the following table BaN6 is barium azide, Ba(N₃)₂, CPD is contact potential difference and 02 is oxygen. The physical structures of the following examples are shown in the drawings.

TABLE 4

| | | CPD (V) | | CPD (V) | |
|---|---|---|---|---|---|
| | CDP (V) | after BaN6, | | after air | |
| Sample # | Al/glass (air) | heating | Δ CDP | exposure | Comments |
| 41-6 | 0.796 | 1.317 | −0.52 | 1.00 | 0.071 M BaN6 in water |
| 42-1 | 0.882 | 1.116 | −0.23 | 0.953 | 0.071 MBaN6 in water |
| 42-2 | 0.873 | 1.594 | −0.721 | 0.883 | 0.13 M BaN6 in water |
| 43-1 | 0.901 | 1.557 | −0.656 | 1.47 | 0.13 M BaN6 in water, |
| | | | | | CPD after 1.5 h in air, |
| | | | | | 1.33 V |
| 43-2 | 0.910 | 1.273 | −0.36 | 0.94 | 0.78 M BaN6 in water, |
| | | | | | thick coating visible |
| 43-3 | 0.936 | 0.739 | +0.2 | | 0.13 M BaN6, heated in |
| | | | | | air |
| 43-4 | 0.813 | 1.515 | −0.7 | 1.236 | 0.13 M BaN6 in water, |
| | | | | | heated in glove box @ |
| | | | | | 150 C. |
| 48-1 | 1.044 | 1.649 | +0.605 | 1.314 | 0.13 M BaN6 in water, |
| | | | | | heated in glove box @ |
| | | | | | 150 C. |
| 48-2 | −0.924 | +0.023 | | | 0.13 M BaN6 in water, |
| | (ITO, | | | | CPD value after spin |
| | UV/03) | | | | coat, no change after |
| | | | | | heating |
| 48-3 | −0.418 | +0.123 | | | 0.13 M BaN6 in water, |
| | (ITO, No | | | | CPD value after spin |
| | UV/03) | | | | coat, no change after |
| | | | | | heating |
| 49-1 | −0.327 | −0.087 | | | 0.12 M BaC1₂ in water, |
| | (IT0, No | | | | CPD after spin coating |
| | UV/03) | | | | |
| 51-1 | 0.902 | 1.107 | 0.2 | 0.985 | 0.13 M BaN6 in |
| | | | | | water/lPA, glove box |
| | | | | | >100 ppm 02, |
| 52-1 | 1.038 | 1.14 | 0.1 | | 0.13 M BaN6 in water, |
| | | | | | heated in glove box @ |
| | | | | | 150 C., >100 ppm 02 |
| 59-4 | 1.263 | 1.782 | 0.5 | 1.468 | 0.13 M BaN6 in water, |
| | | | | | heated in glove box @ |
| | | | | | 150 C., <10 ppm 02, |
| | | | | | new Al/glass |
| 59-5 | 1.040 | 1.486 | 0.4 | 1.48 | 0.13 M BaN6 in water, |
| | | | | | heated in glove box @ |
| | | | | | 150 C., <10 ppm 02, old |
| | | | | | Al/glass |
| 60-1 | 1.063 | 1.477 | 0.4 | 1.417 | 1 mL BaN6, 5 mL |
| | | | | | water, 2.4 mL IPA, |
| | | | | | heated in glove box @ |
| | | | | | 150 C., <10 ppm 02, |
| | | | | | new_Al/glass |
| 60-2 | 1.011 | 1.322 | 0.3 | 1.3 | 2 mL, BaN6, 0.5 mL |
| | | | | | DMSO, heated in glove |
| | | | | | box @ 150 C., <10 ppm |
| | | | | | 0₂, new Al/glass |

Al/glass having a CPD of 1.150 V was loaded in a glove box. The Al/glass after air exposure had a CPD of 1.044 V. The Al/glass was spin coated with barium azide (BaN6) at 4000 rpm, brought into the glove box and heated to 150° C. for ten minutes. The CPD was then 1.649 V. After exposure to air the CPD was 1.314 V. This was a reproduced experiment of an experiment conducted a few days earlier, showing a large change in work function.

40-48.1 used the 0.13 M Ba azide in water solution.

### EXAMPLE 6

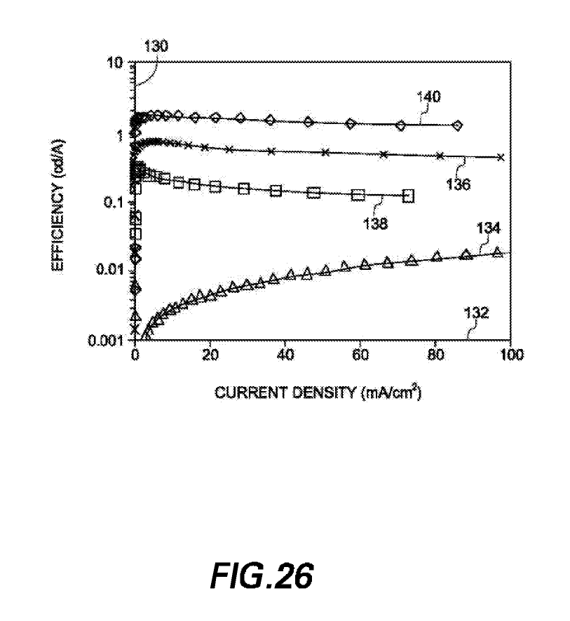

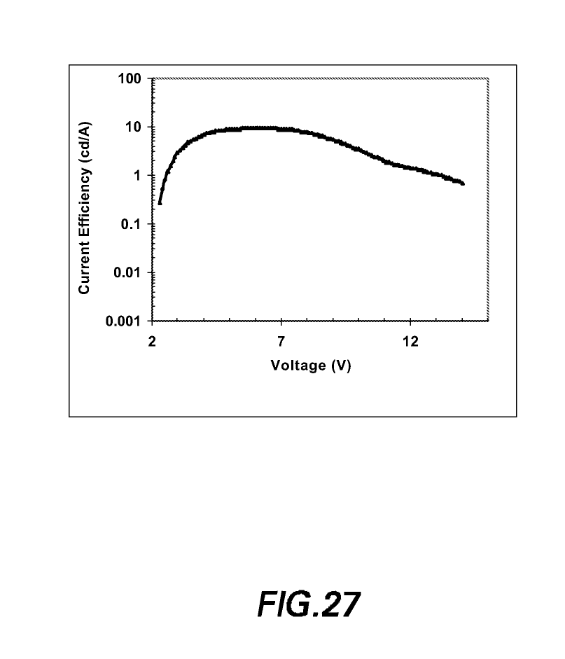

An organic light emitting device was fabricated as follows: A glass substrate precoated with ITO (indium doped tin oxide) was cleaned with nitrogen blow gun and ample isopropanol. It was then rinsed with DI water in a quick dump followed with sonication in 2% Alconox bath. It was placed in the quick dump, and rinsed with DI water again, followed with drying in a rinse/drier and ultraviolet radiation/ozone cleaning. A layer of poly(3,4-ethylenedioxythiophene)/polystyrene sulfonate (PEDOT/PSS) having a thickness of about 60 nm was deposited by spin coating on the ITO side of the cleaned ITO-coated glass, and baked for 10 minute at 110° C. in a nitrogen oven. The coated substrate was then cooled in a nitrogen dry box, followed by spin coating a layer of green organic EL polymer (Sumation 1304) having a thickness of about 80 nm on top of the PEDOT/PSS layer. The substrate was then transferred into an Argon glove box, baked at 130° C. for 15 minutes, and cooled to room temperature. It was then transferred out of the box. A layer of barium azide having a thickness of about 14 nm was deposited by spin coating aqueous azide solution (20% v/v) prepared by diluting a concentrated aqueous barium azide solution, purchased from Sigma-Aldrich, with DI water and isopropanol. The substrate was subsequently transferred into the glove box, baked at 150° C. for 10 minutes. A layer of aluminum having a thickness of about 200 nm was vapor deposited onto the azide coated substrate in Kurdex thermal evaporator. Then the entire multilayer ensemble was encapsulated with a glass slide and sealed with epoxy. Luminance, current density, and bias voltage were measured with a photodiode and a source meter. Current efficiency and power efficiency were calculated as shown in FIGS. 26 and 27.

### EXAMPLE 7

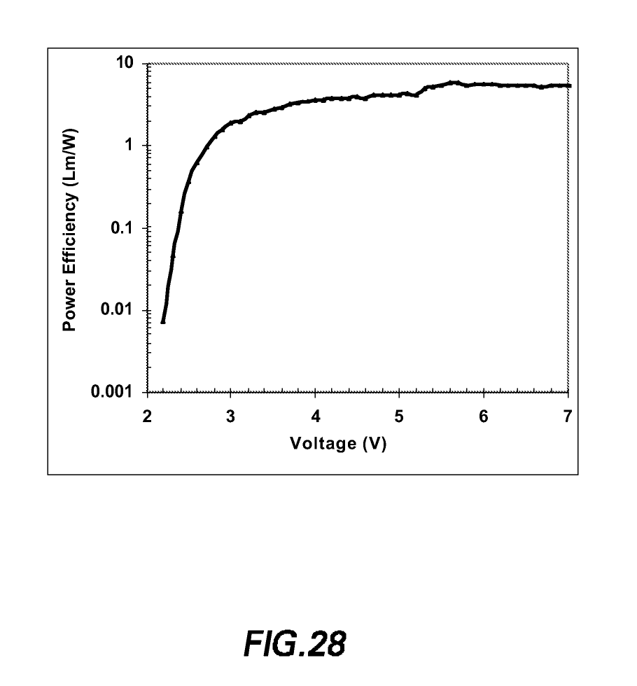

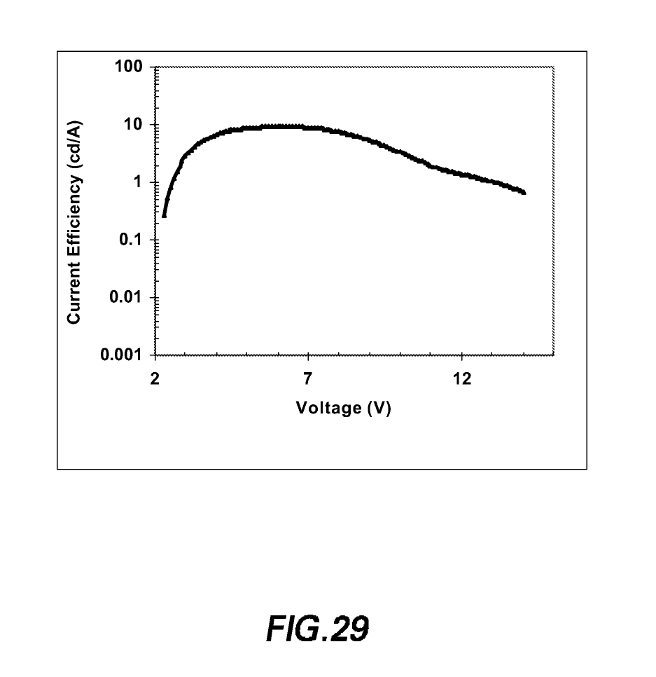

Another organic light emitting device was fabricated as follows: A glass substrate precoated with ITO was cleaned in acetone/ultrasonic bath and isopropanol/ultrasonic bath for 5 minutes, respectively. It was then scrubbed in Alconox aqueous solution, rinsed with ample DI water, and sonicated in DI water, acetone, and isopropanol bath for 5 minutes, respectively. It was dried at 150° C. for 2 hours, cooled in ambient atmosphere, and cleaned with ultraviolet radiation and ozone. A layer of poly(3,4-ethylenedioxythiophene)/polystyrene sulfonate (PEDOT/PSS) having a thickness of about 60 nm was deposited by spin coating on the ITO side of the cleaned ITO-coated glass, and baked for 20 minute at 180° C. in ambient atmosphere. The coated substrate was then transferred into an Argon glove box, followed by spin coating a layer of green organic EL polymer (Sumation 1304) with a thickness of about 80 nm on top of the substrate. After being baked at 130° C. in the box for 10 minutes, the coated substrate was cooled to room temperature, and transferred out of the box. A layer of barium azide mixed with polyethylene glycol (Mw=35,000, purchased from Sigma-Aldrich) having a thickness of about 20 nm was deposited by spin coating on the top of green EL polymer. The substrate was subsequently transferred into the glove box, baked at 200° C. for 10 minutes. A layer of aluminum having a thickness of about 120 nm was vapor deposited onto the azide coated substrate in a thermal evaporator. Then the entire multilayer ensemble was encapsulated with a glass slide and sealed with epoxy. Luminance, current density, and bias voltage were measured with a photodiode and a source meter. Current efficiency and power efficiency were calculated as shown in FIGS. 28 and 29.

Polyethylene glycol has been used together with the azide to enhance its film forming properties.

### EXAMPLE 8

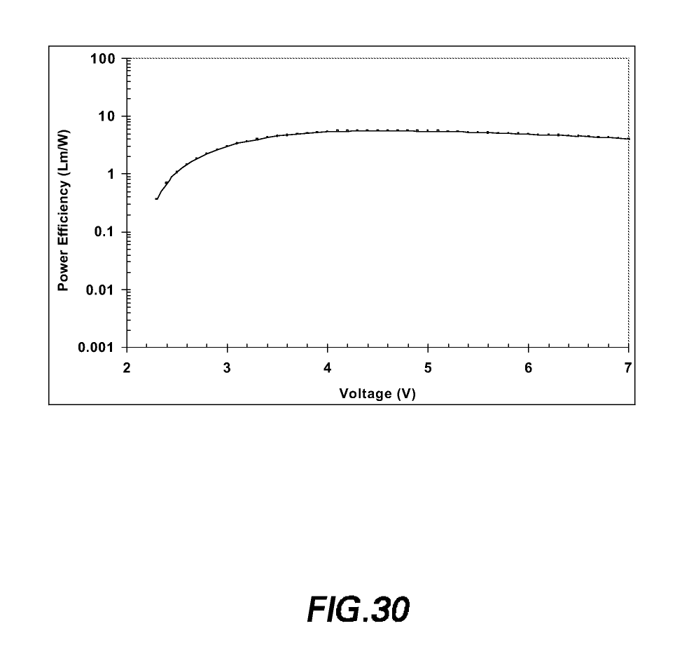

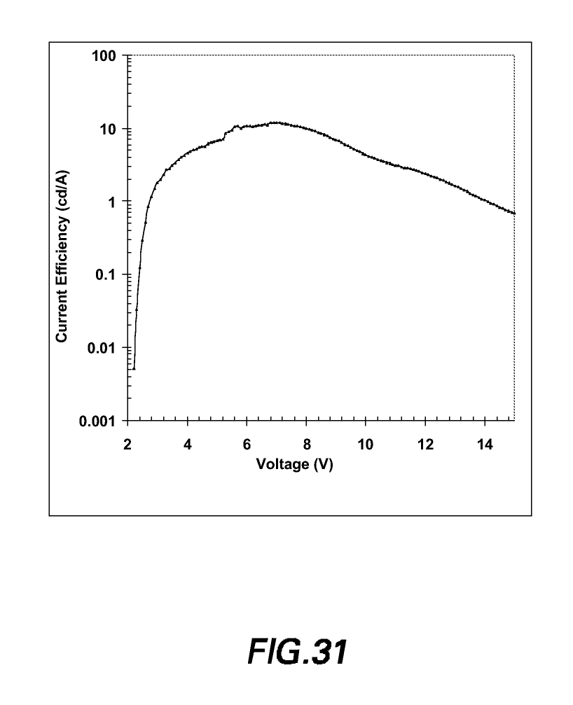

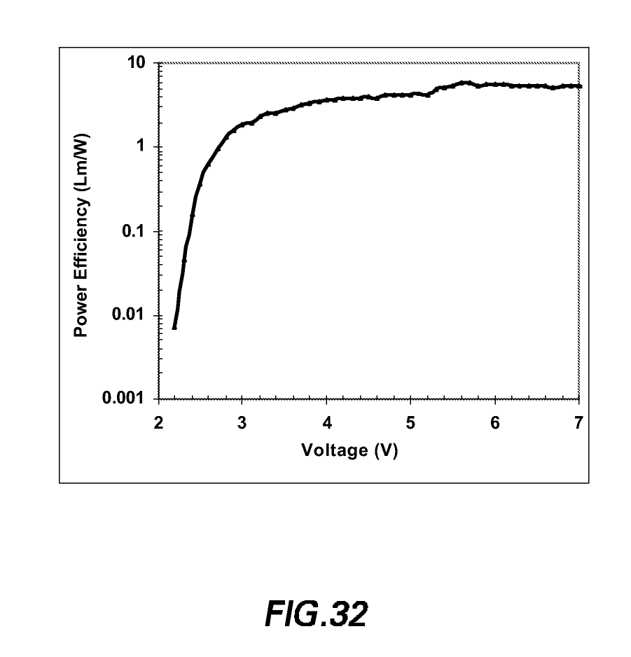

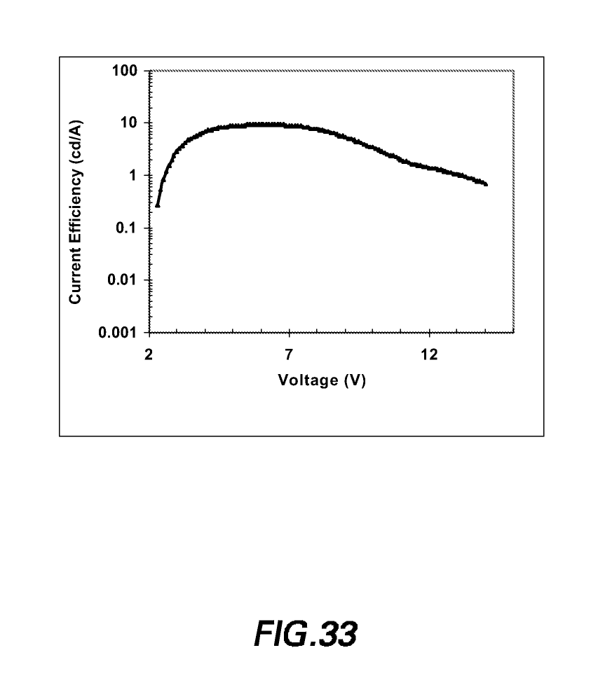

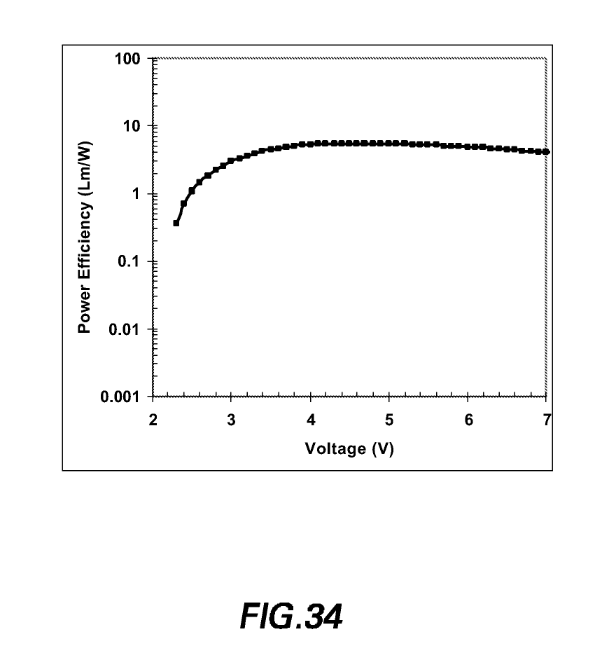

An organic light emitting device (OLED) having the structure of ITO/PEDOT/Sumation 1304/Al was fabricated as follows: A glass substrate precoated with ITO (indium doped tin oxide) was cleaned with a nitrogen blow gun and ample isopropanol. It was then rinsed with DI water in a quick dump followed with sonication in 2% Alconox bath. It was placed in the quick dump, and rinsed with DI water again, followed with drying in a rinse/drier and ultraviolet radiation/ozone cleaning. A layer of poly(3,4-ethylenedioxythiophene)/polystyrene sulfonate (PEDOT/PSS) having a thickness of about 60 nm was deposited by spin coating on the ITO side of the cleaned ITO-coated glass, and baked for 10 minute at 110° C. in a nitrogen oven. The coated substrate was then cooled in a nitrogen dry box, followed by spin coating a layer of green organic EL polymer (Sumation 1304) having a thickness of about 80 nm on top of the PEDOT/PSS layer. Sumation 1304 is a light emitting polymer made by Sumitoma. It is used as an emission layer. The substrate was then transferred into an Argon glove box, baked at 130° C. for 15 minutes, and cooled to room temperature. Barium azide is coated as follows: 0.7 M concentrated aqueous barium azide solution is diluted with DI water and isopropanol. The diluted solution (20% v/v) is coated onto the cathode with 4000 RPM (rate per minute) spin speed, yielding a thickness of about 14 nm. The experiment is repeated using PEG (polyethylene glycol) to improve wetting. A layer of aluminum having a thickness of about 200 nm was vapor deposited onto the azide coated substrate in Kurdex thermal evaporator. Then the entire multilayer ensemble was encapsulated with a glass slide and sealed with epoxy. Luminance, current density, and bias voltage were measured with a photodiode and a source meter. FIG. 30 shows the current efficiency v. Voltage, and FIG. 31 shows the power efficiency v. voltage for the first OLED. FIG. 32 is another graph showing the current efficiency v. voltage and FIG. 33 is another graph showing the power efficiency v. voltage for the OLED made using the PEG.

The previously described embodiments of the present invention have many advantages, including, providing OLED devices with greater conductivity leading to possible increases in OLED light emitting efficiencies.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An OLED device having a cathode layer comprising a reaction product of at least one metal precursor capable of releasing at least one low work function metal when exposed to heat or light.

2. The OLED device of claim 1 wherein the at least one low work function metal has a work function value of less than 3.0 eV.

3. The OLED device of claim 1 wherein the at least one low work function metal is selected from the group consisting essentially of the alkali metal series of elements in Group 1 of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); and the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium.

4. The organic light emitting device of claim 1, wherein the low work function metal comprises barium.

5. The organic light emitting device of claim 1, wherein the metal precursor comprises an organometallic compound having a formula RₓM, wherein M is a metal, ₓ has a value of from 1 to 3, the value being the valence of the metal and R is an aliphatic or aromatic radical.

6. The organic light emitting device of claim 1, wherein the metal precursor comprises an organometallic compound having a formula RₓM, wherein M is a Group II metal, or a lanthanide series metal or any combinations thereof, ₓ has a value of 2 when M is a group II metal and a value of from 2 to 3 when M is a lanthanide series metal, and R is an aliphatic or aromatic radical.

7. The organic light emitting device of claim 1, wherein the metal precursor comprises a material comprising a cyclopentadienyl derivative of an alkaline-earth metal, bis(tetra-i-propyl-cyclopentadienyl)barium, bis(tetra-i-propyl-cyclopentadienyl)calcium, bis(penta-isopropylcyclopentadienyl)M, where M is calcium, barium or strontium, bis(tri-t-butylcyclopentadienyl)M; wherein M is calcium, barium or strontium, a cyclopentadienyl derivative of a lanthanide transition metal, a fluorenyl derivative of an alkaline-earth metal, bis(fluorenyl)calcium, bis(fluorenyl)barium, or a fluorenyl derivative of a lanthanide transistion metal or any combinations thereof.

8. The organic light emitting device of claim 1, wherein the metal precursor comprises a compound of formula M(N₃)ₓ, wherein M is alkali metal series of elements in Group 1 (IUPAC style) of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is a rare earth metal.

9. The organic light emitting device of claim 1, wherein the metal precursor comprises barium bis azide of the formula Ba(N₃)₂.

10. An organic light emitting device comprising:
a) a substrate,
b) at least one cathode layer covering at least part of one surface of the substrate, the cathode layer comprising a reaction product from decomposing at least one metal precursor of formula M(N₃)ₓ, wherein M is selected from the group consisting essentially of the alkali metal series of elements in Group 1 (IUPAC style) of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is a rare earth metal;
c) an anode layer material covering at least a portion of a second substrate; and
d) an organic light emitting material positioned between the cathode layer and the anode layer whereby light is emitted when opposing charges are applied to the anode and cathode layers.

11. The organic light emitting device of claim 10, wherein the cathode layer material comprises barium.

12. The organic light emitting device of claim 10, wherein the metal precursor comprises an organometallic compound having a formula R₂M, wherein M is an alkaline earth metal, and R is an aliphatic or aromatic radical or a substituted aliphatic or aromatic radical.

13. The organic light emitting device of claim 10, wherein the metal precursor comprises an organometallic compound having a formula RₓM, wherein M is a Group II metal, or a lanthanide series metal or any combinations thereof, wherein R is an aliphatic or aromatic radical and wherein ₓ has a value of 2 when M is a group II metal and a value of from 2 to 3 when M is a lanthanide series metal.

14. The organic light emitting device of claim 10, wherein the metal precursor comprises a material comprising a cyclopentadienyl derivative of an alkaline-earth metal, bis(tetra-i-propyl-cyclopentadienyl)barium, bis(tetra-i-propyl-cyclopentadienyl)calcium, bis(penta-isopropylcyclopentadienyl)M, where M is calcium, barium or strontium, and bis(tri-t-butylcyclopentadienyl)M wherein M is calcium, barium or strontium: a cyclopentadienyl derivative of a lanthanide transition metal, a fluorenyl derivative of an alkaline-earth metal, bis(fluorenyl)calcium, bis(fluorenyl)barium, or a fluorenyl derivative of a lanthanide transistion metal or any combinations thereof.

15. The organic light emitting device of claim 10, wherein the metal precursor comprises a compound of formula M(N₃)ₓ, wherein M is selected from the group consisting essentially of the alkali metal series of elements in Group 1 (IUPAC style) of the periodic table: including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is a rare earth metal.

16. The organic light emitting device of claim 10, wherein the metal precursor comprises barium bis azide.

17. A method of making an organic light emitting device comprising:
a) applying to a substrate in atmospheric air a solution of at least one metal precursor comprising an azide of at least one metal, M(N₃)ₓ, wherein M is selected from the group consisting essentially of the alkali metal series of elements in Group 1 (IUPAC style) of the periodic table: including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the rare-earth metals, in group IIIb of the periodic table: the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is a rare earth metal.
b) exposing the at least one metal precursor to heat or light to release the at least one metal.

18. The method of claim 17, wherein the at least one metal precursor is barium bis azide.

19. A method of making an organic light emitting diode comprising the steps of:
a) providing at least one metal precursor capable of transforming into a deposited, metal-containing layer;
b) forming a layer comprising the at least one metal precursor atop the substrate;
c) converting the precursor layer so as to form a deposited, metal-containing cathode;
d) combining a light emitting organic layer with the cathode and;
e) combining an anode with the cathode and light emitting layer, the light emitting layer being positioned between the cathode and the anode.

20. The method of claim 19, wherein the at least one metal precursor comprises a compound of formula M(N₃)ₓ, wherein M is M is selected from the group consisting essentially of the alkali metal series of elements in Group 1 (IUPAC style) of the periodic table:including lithium (Li), sodium (Na), potassium (K), rubidium (Rb), caesium (Cs), and francium (Fr); the alkaline earth metals series of elements in Group 2 of the periodic table: beryllium (Be), magnesium (Mg), calcium (Ca), strontium (Sr), barium (Ba) and radium (Ra); the lanthanides, including lanthanum, cerium, praseodymium, neodymium, promethium, samarium, europium, gadolinium, terbium, dysprosium, holmium, erbium, thulium, ytterbium, and lutetium, and ₓ has a value of from 1 to 3, ₓ having a value of one when M is an alkali metal, a value of 2 when M is an alkaline earth metal and a value of 2 or 3 when M is selected from the lanthanides.

21. The method of claim 19 wherein the at least one metal precursor is a metal azide.

22. The method of claim 19 wherein the at least one metal precursor is barium bis azide.

23. The method of claim 19, wherein the converting is accomplished using an energy source selected from the group consisting of light, heat, electron beam irradiation, ion beam irradiation, and mixtures thereof.

24. The method of claim 19, wherein the at least one metal precursor is applied as a fluid.

25. The method of claim 19 wherein the cathode has a work function value of less than 3.0 eV.

26. A light panel comprising an organic light emitting device according to claim 1.

27. The light panel of claim 26, wherein the cathode layer material comprises barium.

28. The light panel of claim 26, wherein the at least one metal precursor comprises barium bis azide.
